(19) United States
(12) Patent Application Publication
(10) Pub. No.: US 2025/0330205 A1
(43) Pub. Date: Oct. 23, 2025

(54) ELECTRONIC DEVICE FOR TRANSMITTING RF SIGNAL, OPERATION METHOD THEREOF, AND STORAGE MEDIUM

(71) Applicant: SAMSUNG ELECTRONICS CO., LTD., Suwon-si (KR)

(72) Inventors: Joonwon JANG, Suwon-si (KR); Minseok Lee, Suwon-si (KR)

(73) Assignee: SAMSUNG ELECTRONICS CO., LTD., Suwon-si (KR)

(21) Appl. No.: 19/187,529

(22) Filed: Apr. 23, 2025

Related U.S. Application Data
(63) Continuation of application No. PCT/KR2025/005309, filed on Apr. 18, 2025.

(30) Foreign Application Priority Data
Apr. 23, 2024 (KR) 10-2024-0054300
Jun. 14, 2024 (KR) 10-2024-0077742

(51) Int. Cl. H04B 1/04; H02J 7/00; H03F 3/24; H03H 11/04

(52) U.S. Cl. CPC H04B 1/0458; H02J 7/0013; H03F 3/245; H03H 11/04; H02J 2207/50; H03F 2200/451; H04B 2001/0416

(57) ABSTRACT

An electronic device may include: a first power control circuit configured to supply a first supply voltage which is based on transmission power; a first power amplifier configured to amplify a first RF signal, based on the first supply voltage; a battery configured to provide at least one reference voltage; a plurality of capacitor banks including a first capacitor bank and a second capacitor bank; and a switch including a plurality of nodes and configured to selectively connect a node corresponding to one of the plurality of capacitor banks to a node corresponding to the first power control circuit based on the first supply voltage.

### CROSS-REFERENCE TO RELATED APPLICATIONS

This application is a continuation application, claiming priority under § 365 (c), of International Application No. PCT/KR2025/005309, filed on Apr. 18, 2025, which is based on and claims priority to Korean Patent Application No. 10-2024-0054300, filed on Apr. 23, 2024, in the Korean Intellectual Property Office, and Korean Patent Application No. 10-2024-0077742, filed on Jun. 14, 2024, in the Korean Intellectual Property Office, the disclosure of each of which is incorporated by reference herein in its entirety.

### BACKGROUND

### 1. Field

The disclosure relates to an electronic device for transmitting an RF signal, an operation method thereof, and a storage medium.

### 2. Description of Related Art

An electronic device may include at least one power amplifier for amplifying RF signals. M ode for controlling the supply voltage Vcc applied to the power amplifier based on the transmission power of the RF signal include an envelope tracking (ET) mode and an average power tracking (APT) mode. In the APT mode, the supply voltage may be controlled based on the transmission power of the RF signal, and the supply voltage may be controlled in time units of slots (or subframes). In the ET mode, the supply voltage may be controlled by tracking the transmission power of the RF signal in real time.

The above-described information may be provided as related art for the purpose of helping understanding of the disclosure. The foregoing cannot be claimed as, or used to determine, the prior art related to the disclosure.

### SUMMARY

According to an aspect of the disclosure, an electronic device may include: a first power control circuit configured to supply a first supply voltage which is based on transmission power; a first power amplifier configured to amplify a first RF signal, based on the first supply voltage; a battery configured to provide at least one reference voltage; a plurality of capacitor banks including a first capacitor bank and a second capacitor bank; and a switch including a plurality of nodes and configured to selectively connect a node corresponding to one of the plurality of capacitor banks, among the plurality of nodes, to a node corresponding to the first power control circuit, among the plurality of nodes, based on the first supply voltage, wherein the switch is further configured to: based on the first supply voltage being in a first reference range, supply the first supply voltage to the first capacitor bank by connecting the node corresponding to the first power control circuit to a node corresponding to the first capacitor bank, among the plurality of nodes; and based on the first supply voltage being in a second reference range, supply the first supply voltage to the second capacitor bank by connecting the node corresponding to the first power control circuit to a node corresponding to the second capacitor bank, among the plurality of nodes, and supply a first reference voltage to the first capacitor bank by connecting a node corresponding to the battery, among the plurality of nodes, to the node corresponding to the first capacitor bank.

According to an aspect of the disclosure, a method for operating an electronic device, may include: adjusting a first supply voltage supplied from a first power control circuit to a first power amplifier based on transmission power; amplifying a first RF signal based on the first supply voltage; based on the first supply voltage being in a first reference range, supplying the first supply voltage to a first capacitor bank by connecting a node corresponding to the first power control circuit, among a plurality of nodes of a switch, to a node corresponding to the first capacitor bank, among the plurality of nodes; and based on the first supply voltage being in a second reference range, supplying the first supply voltage to a second capacitor bank by connecting the node corresponding to the first power control circuit to a node corresponding to the second capacitor bank, among the plurality of nodes, and supplying a first reference voltage to the first capacitor bank by connecting a node corresponding to a battery, among the plurality of nodes, to the node corresponding to the first capacitor bank.

According to an aspect of the disclosure, a computer-readable non-transitory storage medium storing instructions, the instructions, when executed by at least one processor of an electronic device, causing the electronic device to perform at least one operation, wherein the at least one operation may include: adjusting a first supply voltage supplied from a first power control circuit to a first power amplifier based on transmission power; amplifying a first RF signal based on the first supply voltage; based on the first supply voltage being in a first reference range, supplying the first supply voltage to a first capacitor bank by connecting a node corresponding to the first power control circuit, among a plurality of nodes of a switch, to a node corresponding to the first capacitor bank, among the plurality of nodes; and based on the first supply voltage being in a second reference range, supplying the first supply voltage to a second capacitor bank by connecting the node corresponding to the first power control circuit to a node corresponding to the second capacitor bank, among the plurality of nodes, and supplying a first reference voltage to the first capacitor bank by connecting a node corresponding to a battery, among the plurality of nodes, to the node corresponding to the first capacitor bank.

### BRIEF DESCRIPTION OF THE DRAWINGS

The above and other objects, features and advantages of the present disclosure will become clearer through the following detailed description together with the accompanying drawings in which:

FIG. 1 is a view illustrating an electronic device in a network environment according to an embodiment;

FIG. 2A is a block diagram illustrating an electronic device for supporting legacy network communication and 5G network communication according to an embodiment;

FIG. 2B is a block diagram illustrating an electronic device for supporting legacy network communication and 5G network communication according to an embodiment;

FIG. 3 is a block diagram illustrating an electronic device including a power amplifier according to an embodiment;

FIG. 4A is a view illustrating an operation mode according to an embodiment;

FIG. 4B is a view illustrating an operation mode according to an embodiment;

FIG. 4C is a view illustrating an operation mode according to an embodiment;

FIG. 5 is a cross-sectional view illustrating a capacitor during charge and

discharge according to an embodiment;

FIG. 6 is a flowchart illustrating an operation method of an electronic device according to an embodiment;

FIG. 7 is a view illustrating connection between components of an electronic device according to an embodiment;

FIG. 8 is a circuit diagram illustrating an electronic device according to an embodiment;

FIG. 9 is a graph illustrating a voltage applied to a capacitor bank connected to a power amplifier according to an embodiment;

FIG. 10 is a view illustrating a replacement of a capacitor bank according to an embodiment;

FIG. 11 is a view illustrating connection between components of an electronic device according to an embodiment;

FIG. 12 is a circuit diagram illustrating an electronic device according to an embodiment; and

FIG. 13 is a view illustrating connection between components of an electronic device according to an embodiment.

### DETAILED DESCRIPTION

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

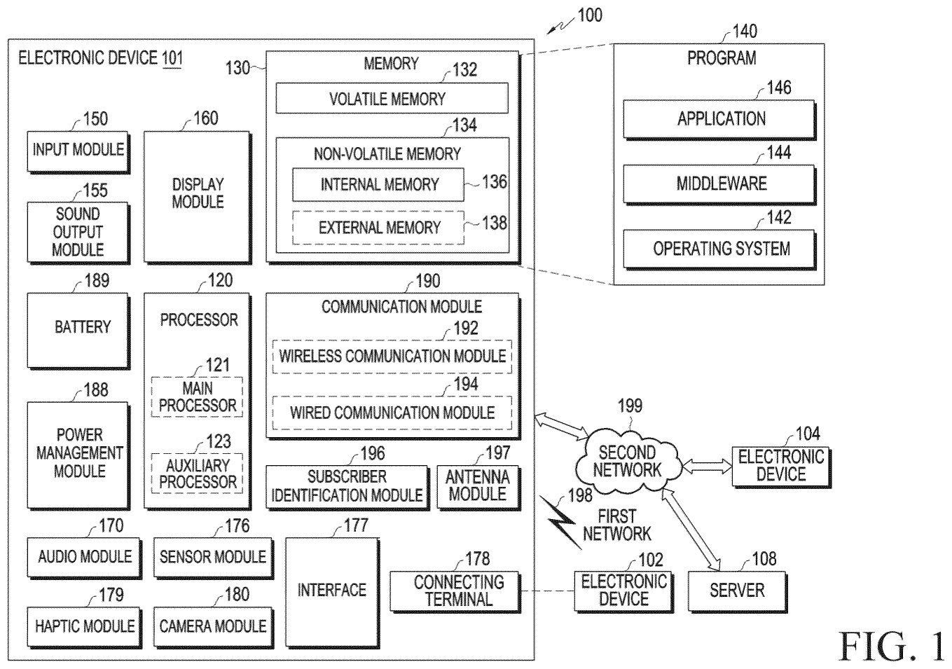

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IM SI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mM TC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

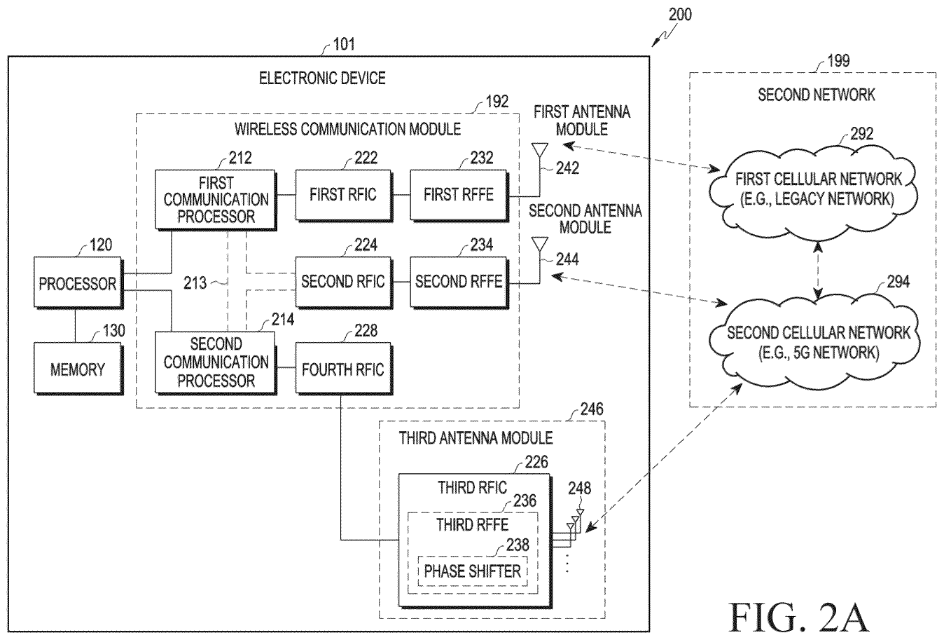

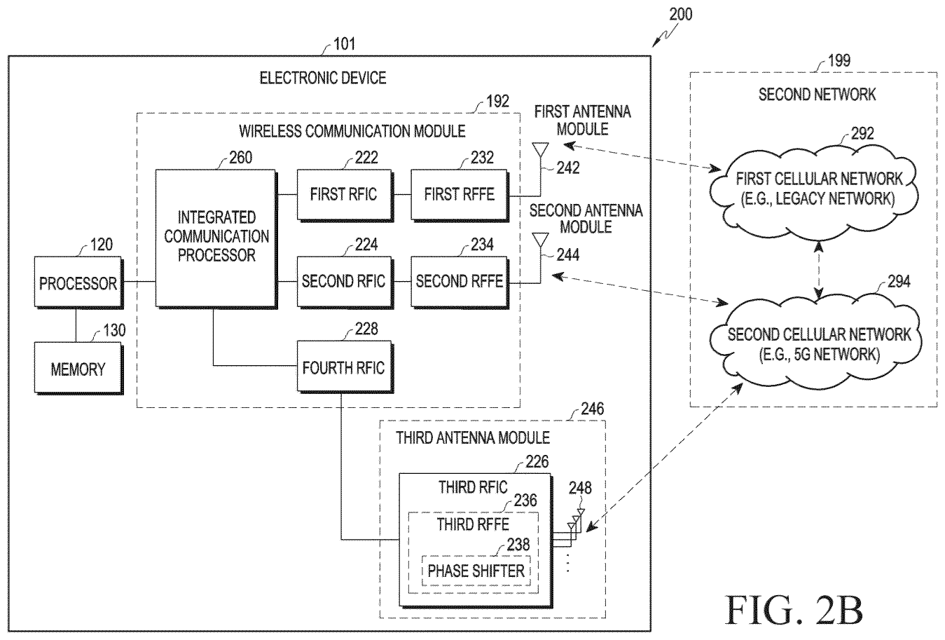

FIG. 2A is a block diagram 200 illustrating an electronic device 101 for supporting legacy network communication and 5G network communication according to an embodiment. Referring to FIG. 2A, the electronic device 101 may include a first communication processor 212, a second communication processor 214, a first radio frequency integrated circuit (RFIC) 222, a second RFIC 224, a third RFIC 226, a fourth RFIC 228, a first radio frequency front end (RFFE) 232, a second RFFE 234, a first antenna module 242, a second antenna module 244, a third antenna module 246, and antennas 248. The electronic device 101 may further include a processor 120 and memory 130. The second network 199 may include a first cellular network 292 and a second cellular network 294. According to an embodiment, the electronic device 101 may further include at least one component among the components of FIG. 1, and the second network 199 may further include at least one other network. According to an embodiment, the first communication processor 212, the second communication processor 214, the first RFIC 222, the second RFIC 224, the fourth RFIC 228, the first RFFE 232, and the second RFFE 234 may form at least part of the wireless communication module 192. According to another embodiment, the fourth R FIC 228 may be omitted or be included as part of the third RFIC 226.

The first communication processor 212 may establish a communication channel of a band that is to be used for wireless communication with the first cellular network 292 or may support legacy network communication via the established communication channel. According to various embodiments, the first cellular network may be a legacy network that includes second generation (2G), third generation (3G), fourth generation (4G), or long-term evolution (LTE) networks. The second CP 214 may establish a communication channel corresponding to a designated band (e.g., from about 6 GHz to about 60 GHz) among bands that are to be used for wireless communication with the second cellular network 294 or may support fifth generation (5G) network communication via the established communication channel. According to an embodiment, the second cellular network 294 may be a 5G network defined by the 3rd generation partnership project (3GPP). Additionally, according to an embodiment, the first CP 212 or the second CP 214 may establish a communication channel corresponding to another designated band (e.g., about 6 GHz or less) among the bands that are to be used for wireless communication with the second cellular network 294 or may support fifth generation (5G) network communication via the established communication channel.

The first communication processor 212 may perform data transmission/reception with the second communication processor 214. For example, data classified as transmitted via the second cellular network 294 may be changed to be transmitted via the first cellular network 292. In this case, the first communication processor 212 may receive transmission data from the second communication processor 214. For example, the first communication processor 212 may transmit/receive data to/from the second communication processor 214 via an inter-processor interface 213. The inter-processor interface 213 may be implemented as, e.g., universal asynchronous receiver/transmitter (UART) (e.g., high speed-UART (HS-UART)) or peripheral component interconnect bus express (PCIe) interface, but is not limited to a specific kind. The first communication processor 212 and the second communication processor 214 may exchange packet data information and control information using, e.g., a shared memory. The first communication processor 212 may transmit/receive various types of information, such as sensing information, information about output strength, and resource block (RB) allocation information, to/from the second communication processor 214.

According to implementation, the first communication processor 212 may not be directly connected with the second communication processor 214. In this case, the first communication processor 212 may transmit/receive data to/from the second communication processor 214 via a processor 120 (e.g., an application processor). For example, the first communication processor 212 and the second communication processor 214 may transmit/receive data to/from the processor 120 (e.g., an application processor) via an HS-UART interface or PCIe interface, but the kind of the interface is not limited thereto. The first communication processor 212 and the second communication processor 214 may exchange control information and packet data information with the processor 120 (e.g., an application processor) using a shared memory.

According to an embodiment, the first communication processor 212 and the second communication processor 214 may be implemented in a single chip or a single package. According to an embodiment, the first CP 212 or the second CP 214, along with the processor 120, an auxiliary processor 123, or communication module 190, may be formed in a single chip or single package. For example, as shown in FIG. 2B, an integrated communication processor 260 may support all of the functions for communication with the first cellular network 292 and the second cellular network 294.

As described above, at least one of the processor 120, the first communication processor 212, the second communication processor 214, or the integrated communication processor 260 may be implemented as a single chip or a single package. In this case, the single chip or single package may include memory (or storage means) storing instructions that cause at least some of operations performed according to various embodiments and a processing circuit (or operation circuit, but the term is not limited) for executing instructions.

Upon transmission, the first RFIC 222 may convert a baseband signal generated by the first communication processor 212 into a radio frequency (RF) signal with a frequency ranging from about 700 MHz to about 3 GHz which is used by the first cellular network 292 (e.g., a legacy network). Upon receipt, the RF signal may be obtained from the first cellular network 292 (e.g., a legacy network) through an antenna (e.g., the first antenna module 242) and be pre-processed via an RFFE (e.g., the first RFFE 232). The first RFIC 222 may convert the pre-processed RF signal into a baseband signal that may be processed by the first CP 212.

Upon transmission, the second RFIC 224 may convert the baseband signal generated by the first CP 212 or the second CP 214 into a Sub6-band (e.g., about 6 GHz or less) RF signal (hereinafter, “5G Sub6 RF signal”) that is used by the second cellular network 294 (e.g., a 5G network). Upon receipt, the 5G Sub6 RF signal may be obtained from the second cellular network 294 (e.g., a 5G network) through an antenna (e.g., the second antenna module 244) and be pre-processed via an RFFE (e.g., the second RFFE 234). The second RFIC 224 may convert the pre-processed 5G Sub6 RF signal into a baseband signal that may be processed by a corresponding processor of the first communication processor 212 and the second communication processor 214.

The third RFIC 226 may convert the baseband signal generated by the second CP 214 into a 5G Above6 band (e.g., from about 6 GHz to about 60 GHz) RF signal (hereinafter, “5G Above6 RF signal”) that is to be used by the second cellular network 294 (e.g., a 5G network). Upon receipt, the 5G Above6 RF signal may be obtained from the second cellular network 294 (e.g., a 5G network) through an antenna (e.g., the antenna 248) and be pre-processed via the third RFFE 236. The third RFIC 226 may convert the pre-processed 5G Above6 RF signal into a baseband signal that may be processed by the second communication processor 214. According to an embodiment, the third RFFE 236 may be formed as part of the third RFIC 226.

According to an embodiment, the electronic device 101 may include the fourth RFIC 228 separately from, or as at least part of, the third RFIC 226. In this case, the fourth RFIC 228 may convert the baseband signal generated by the second communication processor 214 into an intermediate frequency band (e.g., from about 9 GHz to about 11 GHz) RF signal (hereinafter, “IF signal”) and transfer the IF signal to the third RFIC 226. The third RFIC 226 may convert the IF signal into a 5G Above6 RF signal. Upon receipt, the 5G Above6 RF signal may be received from the second cellular network 294 (e.g., a 5G network) through an antenna (e.g., the antenna 248) and be converted into an IF signal by the third RFIC 226. The fourth RFIC 228 may convert the IF signal into a baseband signal that may be processed by the second communication processor 214.

According to an embodiment, the first RFIC 222 and the second RFIC 224 may be implemented as at least part of a single chip or single package. According to various embodiments, when the first RFIC 222 and the second RFIC 224 in FIG. 2A or 2B are implemented as a single chip or a single package, they may be implemented as an integrated RFIC. In this case, the integrated RFIC is connected to the first RFFE 232 and the second RFFE 234 to convert a baseband signal into a signal of a band supported by the first RFFE 232 and/or the second RFFE 234, and may transmit the converted signal to one of the first RFFE 232 and the second RFFE 234. According to an embodiment, the first RFFE 232 and the second RFFE 234 may be implemented as at least part of a single chip or single package. According to an embodiment, at least one of the first antenna module 242 or the second antenna module 244 may be omitted or be combined with another antenna module to process multi-band RF signals.

According to an embodiment, the third RFIC 226 and the antenna 248 may be disposed on the same substrate to form the third antenna module 246. For example, the wireless communication module 192 or the processor 120 may be disposed on a first substrate (e.g., a main painted circuit board (PCB)). In this case, the third RFIC 226 and the antenna 248, respectively, may be disposed on one area (e.g., the bottom) and another (e.g., the top) of a second substrate (e.g., a sub PCB) which is provided separately from the first substrate, forming the third antenna module 246. Placing the third RFIC 226 and the antenna 248 on the same substrate may shorten the length of the transmission line therebetween. This may reduce a loss (e.g., attenuation) of high-frequency band (e.g., from about 6 GHz to about 60 GHz) signal used for 5G network communication due to the transmission line. Thus, the electronic device 101 may enhance the communication quality with the second cellular network 294 (e.g., a 5G network).

According to an embodiment, the antenna 248 may be formed as an antenna array which includes a plurality of antenna elements available for beamforming. In this case, the third RFIC 226 may include a plurality of phase shifters 238 corresponding to the plurality of antenna elements, as part of the third RFFE 236. Upon transmission, the plurality of phase shifters 238 may change the phase of the 5G Above6 RF signal which is to be transmitted to the outside (e.g., a 5G network base station) of the electronic device 101 via their respective corresponding antenna elements. Upon receipt, the plurality of phase shifters 238 may change the phase of the 5G Above6 RF signal received from the outside to the same or substantially the same phase via their respective corresponding antenna elements. This enables transmission or reception via beamforming between the electronic device 101 and the outside.

The second cellular network 294 (e.g., a 5G network) may be operated independently (e.g., as standalone (SA)) from, or in connection (e.g., as non-standalone (NSA)) with the first cellular network 292 (e.g., a legacy network). For example, the 5G network may have the access network (e.g., 5G radio access network (RAN) or next generation RAN (NG RAN)) but may not have the core network (e.g., next generation core (NGC)). In this case, the electronic device 101, after accessing a 5G network access network, may access an external network (e.g., the Internet) under the control of the core network (e.g., the evolved packet core (EPC)) of the legacy network. Protocol information (e.g., LTE protocol information) for communication with the legacy network or protocol information (e.g., New Radio (NR) protocol information) for communication with the 5G network may be stored in the memory 230 and be accessed by other components (e.g., the processor 120, the first communication processor 212, or the second communication processor 214).

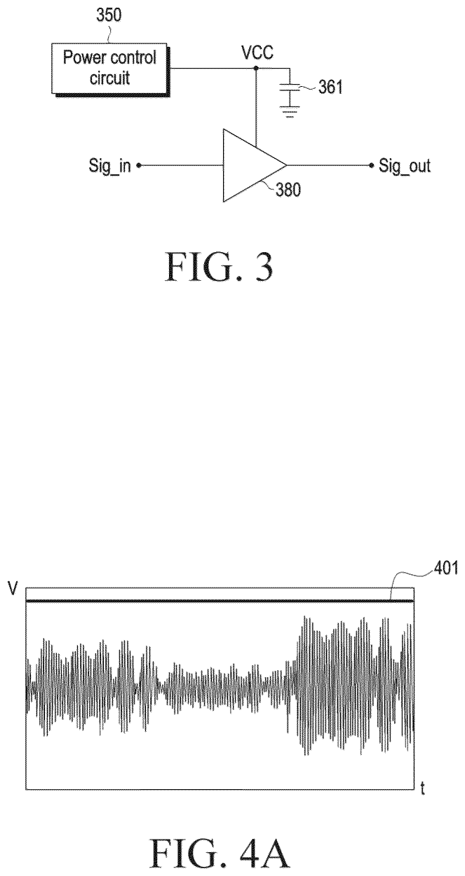

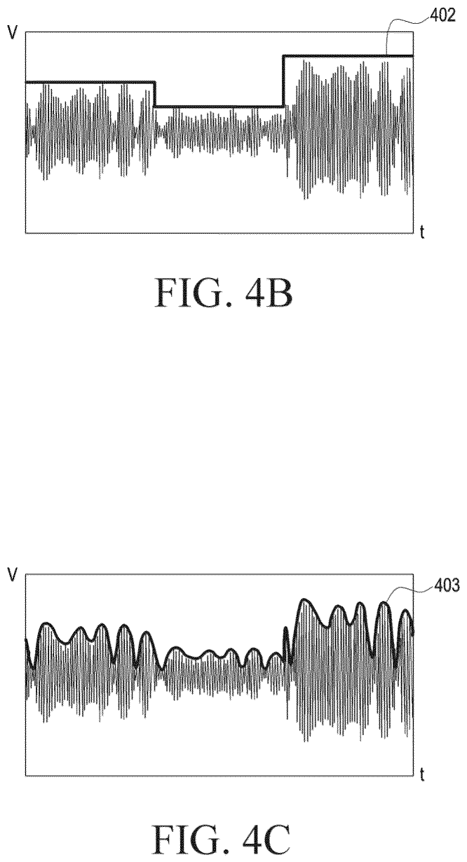

FIG. 3 is a block diagram illustrating an electronic device including a power amplifier according to an embodiment. The embodiment related to FIG. 3 is described in greater detail with reference to FIGS. 4A-C. FIGS. 4A-C are views illustrating an operation mode according to an embodiment.

According to various embodiments, an electronic device 101 may include at least one of a power amplifier 380, a power control circuit 350, or a capacitor 361.

According to an embodiment, the communication processor (e.g., at least one of the first communication processor 212, the second communication processor 214, or the integrated communication processor 260) may provide a baseband signal for transmission to an RFIC (e.g., at least one of the first RFIC 222, the second RFIC 224, the third RFIC 226, or the fourth RFIC 228). Alternatively, the communication processor (e.g., at least one of the first communication processor 212, the second communication processor 214, or the integrated communication processor 260) may receive and process a baseband signal for reception from the RFIC (e.g., at least one of the first R FIC 222, the second RFIC 224, the third R FIC 226, or the fourth RFIC 228).

According to an embodiment, the processor 120 may execute a call application. According to an embodiment, the processor 120 may execute the call application. For example, the processor 120 may perform an outgoing call based on a call outgoing request (e.g., selection of an icon for an outgoing request or a voice command, but is not limited thereto) from the user, or may perform an incoming call based on a response request (e.g., selection of an icon for reception or a voice command, but is not limited thereto) to the incoming call, but is not limited thereto. For example, the processor 120 may perform a call based on an application (e.g., a server-client based application) providing at least one call function in addition to the call application (e.g., an application based on an internet protocol multimedia subsystem (IM S)), but one of ordinary skill in the art will understand that the type of the application is not limited.

For example, the processor 120 may output a voice for a call through a receiver. The receiver may be a device for outputting a voice, but is not limited thereto. For example, when the user grips the electronic device 101, the receiver may be disposed to be in contact with (or adjacent to) the user's ear, but the placement position thereof is not limited thereto. For example, the processor 120 may set the receiver as a default output device for a call. For example, the processor 120 may be configured to output a voice for a call through the receiver, based on an accessory for another voice output, e.g., a voice output device (e.g., a wired earphone, but not limited thereto) wiredly connected or a voice output device (e.g., a wireless earphone, or a wireless speaker, but not limited thereto) wirelessly connected not being operatively connected (e.g., which may be a physical insertion or establishment of a wireless communication channel (or connection), but not limited thereto). For example, the processor 120 may be configured to output a voice for a call through the receiver based on not being set to the speakerphone mode, but is not limited thereto.

According to an embodiment, the RFIC (e.g., at least one of the first RFIC 222, the second R FIC 224, the third R FIC 226, or the fourth RFIC 228) may generate an RF signal (e.g., Sig_in of FIG. 3) corresponding to, e.g., a baseband signal for transmission and may provide the RF signal to the power amplifier 380. The power amplifier 380 may be included in an RFFE (e.g., at least one of the first RFFE 232, the second RFFE 234, or the third RFFE 236). The RFFE may be configured in the form of a power amplifier module (PAM), a front end module (FEM), a power amplifier module including duplexer (PAM ID), an LNA and PAM with integrated duplexer or diplexer (LPAMID), and a PA with integrated low noise amplifier and filter (LPAMIF), but the implementation form thereof is not limited thereto. Those skilled in the art will understand that a filter and/or an antenna switching module (ASM) may be implemented to be further included in the RFFE. Meanwhile, in FIG. 3, one power amplifier 380 is illustrated as being included in the electronic device 101, but this is for convenience of description, and it is understood by one of ordinary skill in the art that a plurality of power amplifiers may be implemented to be included in the electronic device 101. Meanwhile, an RFFE including an RFIC (e.g., at least one of the first RFIC 222, the second RFIC 224, the third RFIC 226, or the fourth RFIC 228) and a power amplifier 380 may be referred to as an RF circuit.

According to an embodiment, the power control circuit 350 (e.g., at least one of a buck/boost converter, a buck converter, or a boost converter) may provide the supply voltage Vcc to the power amplifier 380 using the supplied power. For example, the power control circuit 350 may provide the supply voltage Vcc to the power amplifier 380 using power supplied from a power source (e.g., the battery 189 or an external power source). The power amplifier 380 may amplify an RF signal provided from an RFIC (e.g., at least one of the first RFIC 222, the second R FIC 224, the third RFIC 226, or the fourth RFIC 228) using a supply voltage Vcc. The power control circuit 350 may be configured to operate according to, e.g., an average power tracking (APT) mode. Alternatively, the power control circuit 350 may operate in a direct mode or an ET mode. When operating in an envelope tracking (ET) mode, the power control circuit 350 may be replaced with a linear amplifier. In one example, when operating according to the direct mode, the supply voltage Vcc 401 of the power amplifier 380 may be set to a designated value as illustrated in FIG. 4A. In the direct mode, the supply voltage 401 having a designated value may be provided to the power amplifier 380 regardless of the magnitude of transmission power for each signal. In this case, wasted power consumption may be relatively large. In another example, when operating according to the APT mode, as illustrated in FIG. 4B, the supply voltage Vcc 402 of the power amplifier 380 may be set (or changed) according to a designated time unit (e.g., slot (or subframe)). For example, in a subframe (or slot) in which the transmission power of the RF signal is set to 10 to 18 dBm, a supply voltage Vcc of 3 V may be supplied to the power amplifier 380, and in a subframe (or slot) in which the transmission power of the RF signal is set to 18 to 24 dBm, a supply voltage Vcc of 4 V may be supplied to the power amplifier 380. In another example, when operating according to the ET mode, as illustrated in FIG. 4C, the supply voltage Vcc 403 of the power amplifier 380 may be set (or changed) in real time according to the magnitude of the transmission power of the RF signal. When operating according to the ET mode, the power control circuit 350 may track the transmission power of the RF signal in real time and provide a supply voltage corresponding to an envelope of the transmission power to the power amplifier 380. The time interval of the setting (or change) of the supply voltage Vcc in the ET mode may be shorter than the time interval of the setting (or change) of the supply voltage Vcc in the APT mode. The communication processor (e.g., at least one of the first communication processor 212, the second communication processor 214, or the integrated communication processor 260) (or a modulator) may determine the magnitude of the supply voltage set in the APT mode or the ET mode, using, e.g., a value 12+Q2 based on the I/Q signal of the baseband signal. The electronic device 101 may include, but is not limited to, at least one of an envelope detector, an envelope shaper, or an amplifier.

According to an embodiment, the power control circuit 350 may provide the supply voltage Vcc to the power amplifier 380 to transmit the RF signal according to the APT mode. For example, the power control circuit 350 may include a switch. Although the on-duration and the off-duration (or the ratio of the on-duration and the off-duration) of the switch may be determined according to the determined magnitude of the supply voltage Vcc, it will be understood by one of ordinary skill in the art that the method in which the power control circuit 350 controls the magnitude of the supply voltage Vcc is not limited. For example, when an RF signal of an ultra-high band (UHB) or an operating band (e.g., a B48 band, a B42 band, an N48 band, an N41 band, an N77 band, an N78 band, or an N79 band) having a relatively wide bandwidth is transmitted, the APT mode may be used, but is not limited thereto. The power control circuit 350 may control a charge amount and/or a discharge amount of the capacitor 361 to supply the determined supply voltage Vcc.

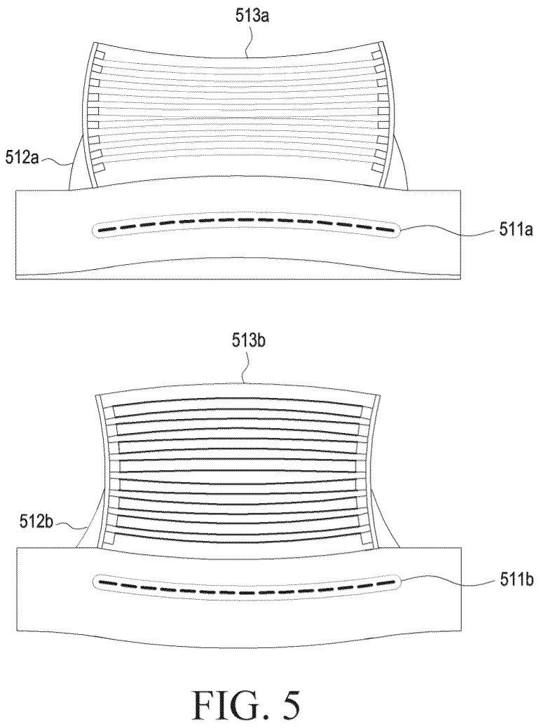

FIG. 5 is a cross-sectional view illustrating a capacitor during charge and discharge according to an embodiment.

According to an embodiment, audible noise may be caused by shaking of the capacitor (e.g., the capacitor 361 of FIG. 3), and the shaking of the capacitor (e.g., the capacitor 361 of FIG. 3) may be caused by shaking of the stacked internal plates when charging and discharging occur due to the structure of the capacitor (e.g., the capacitor 361 of FIG. 3). For example, in order to reduce noise generated by shaking of the capacitor (e.g., the capacitor 361 of FIG. 3), it is necessary to prevent the transfer of shaking or to prevent shaking. For example, in order to reduce the amount of shaking, the amount of charged voltage may be reduced or the amount of discharged voltage may be reduced. According to an embodiment, noise may be reduced by reducing capacitor shaking by limiting the maximum swing width of charging or discharging through a capacitor bank (or capacitor filter) described below. For example, a capacitor (e.g., the capacitor 361 of FIG. 3) may be charged during a transmission period and discharged during a non-transmission period. For example, during discharge, a capacitor (e.g., the capacitor 361 of FIG. 3) may have a first shape 513a, and during charging, a capacitor (e.g., the capacitor 361 of FIG. 3) may have a second shape 513b. A change in shape according to charging and discharging of the capacitor (e.g., the capacitor 361 of FIG. 3) may cause a change in the shape of surrounding hardware, e.g., a PCB or a solder. For example, when the capacitor (e.g., the capacitor 361 of FIG. 3) has the first shape 513a, the PCB may have the first shape 511a, and the solder may have the first shape 512a. For example, when the capacitor (e.g., the capacitor 361 of FIG. 3) has the second shape 513b, the PCB may have the second shape 511b, and the solder may have the second shape 512b. Vibration may occur due to such a change in shape, and when the frequency of the corresponding vibration is included in the audible band 20 to 20000 Hz, audible noise may be heard by the user. When the capacitor (e.g., the capacitor 361 of FIG. 3) is disposed close to the receiver of the electronic device 101, audible noise may be heard during a phone call, thereby deteriorating call quality. In particular, in the small electronic device 101, since the mounting area is small, the distance between the capacitor (e.g., the capacitor 361 of FIG. 3) and the receiver may be designed to be very short, which may cause call quality degradation. Further, when an operating frequency band requiring relatively high transmission power and/or an operating frequency band supporting a relatively wide bandwidth is used, a relatively high supply voltage Vcc may be required. For example, the B38 frequency band having a bandwidth of 10 MHz may require a relatively low supply voltage Vcc of 2.9 V when the target transmission power is 23 dBm. However, e.g., the B48 frequency band having a bandwidth of 20 MHz may require a relatively high supply voltage Vcc of 4.4 V when the target transmission power is 24 dBm. For example, the N41 frequency band having a bandwidth of 50 MHz or more may require a relatively high supply voltage Vcc of 5.0 V when the target transmission power is 26 dBm. When a relatively high supply voltage Vcc is applied to the capacitor (e.g., the capacitor 361 of FIG. 3) and then discharged, a voltage difference during charging-discharging may also be relatively large. The relatively large voltage difference during charging-discharging may cause relatively large audible noise.

According to an embodiment, the operation of the electronic device 101 may be understood as an operation of at least one of the components of the electronic device 101. For example, the operation of the electronic device 101 may be understood as an operation of at least one processor (e.g., at least one of the processor 120, the first communication processor 212, the second communication processor 214, or the integrated communication processor 260). For example, at least one processor (e.g., at least one of the processor 120, the first communication processor 212, the second communication processor 214, or the integrated communication processor 260) may control at least one of the components of the electronic device 101. According to an embodiment, a storage medium (e.g., the memory 130) for storing computer-readable instructions may be provided. The instructions stored in the storage medium (e.g., the memory 130) may enable the electronic device 101 to perform at least one operation, when executed by the at least one processor 120, 212, 214, or 260 of the electronic device 101.

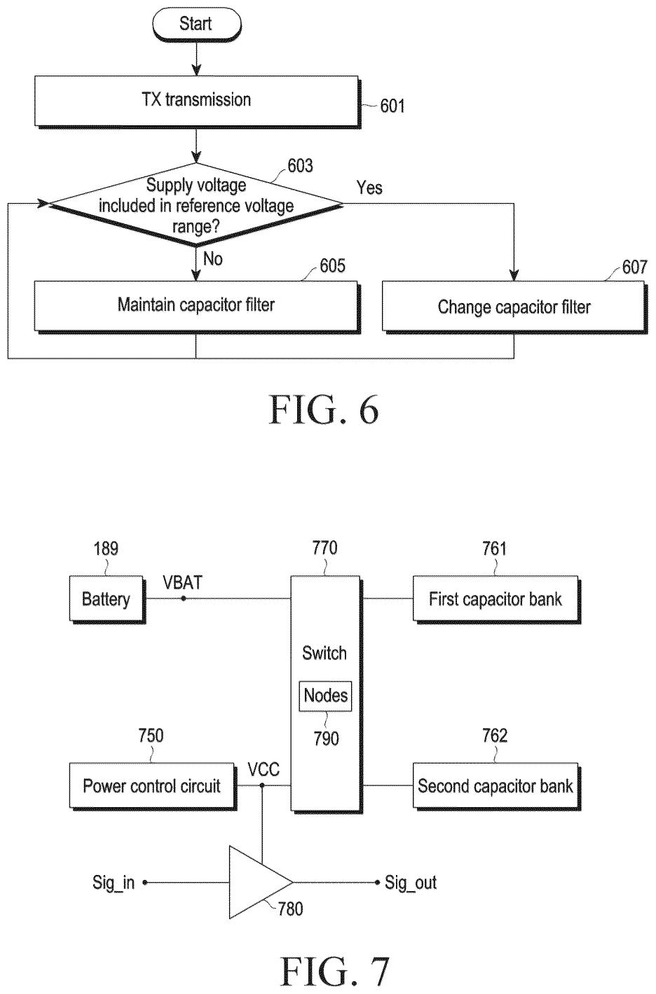

FIG. 6 is a flowchart illustrating an operation method of a wireless power transmission device according to an embodiment.

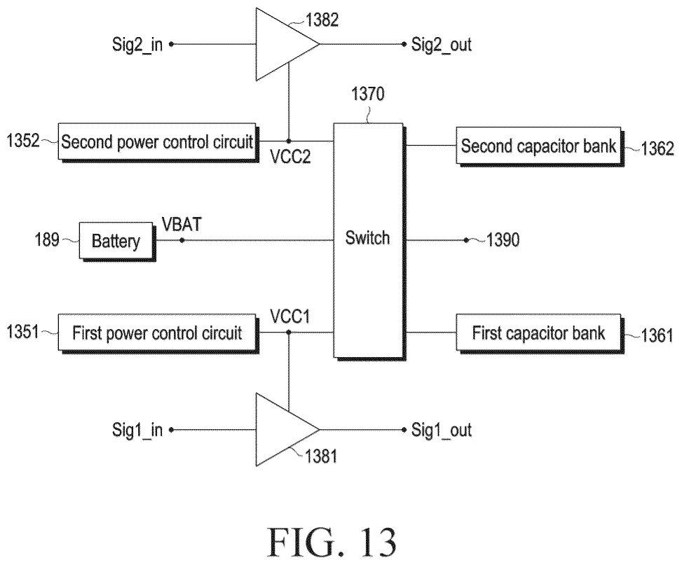

The embodiment of FIG. 6 may be applied to embodiments of other drawings (e.g., FIGS. 7 to 13) described below. The embodiment of FIG. 6 may be described in detail by embodiments of other drawings (e.g., FIGS. 7 to 13) described below. For example, the embodiment of FIG. 6 may be applied to the embodiment of FIG. 7, the embodiment of FIG. 11, and the embodiment of FIG. 13. For example, in the description of FIG. 6, the “supply voltage” may be the supply voltage (e.g., VCC) of the embodiment of FIG. 7, the supply voltage (e.g., VCC) of the embodiment of FIG. 11, or the supply voltage (e.g., VCC1 and VCC2) of the embodiment of FIG. 13. For example, in the description of FIG. 6, the “reference voltage range (or reference range)” may be the reference range (e.g., the first reference range or the second reference range) of the embodiment of FIG. 7, the reference range (e.g., the first reference range, the second reference range, the third reference range, the fourth reference range) of the embodiment of FIG. 11, or the reference range (e.g., the first reference range or the second reference range) of the embodiment of FIG. 13. For example, in the description of FIG. 6, the “capacitor filter” may be the capacitor banks (e.g., 761, 762) of FIG. 7, the capacitor banks (e.g., 1161, 1162, 1163, 1164) of FIG. 11, or the capacitor banks (e.g., 1361, 1362) of FIG. 13. For example, in the description of FIG. 6, the “power amplifier” may be the power amplifier (e.g., 780) of FIG. 7, the power amplifier (e.g., 1180) of FIG. 11, or the power amplifier (e.g., 1381, 1382) of FIG. 13. For example, in the description of FIG. 6, the “power control circuit” may be the power control circuit (e.g., 750) of FIG. 7, the power control circuit (e.g., 1150) of FIG. 11, or the power control circuit (e.g., 1351, 1352) of FIG. 13.

In the embodiment of FIG. 6, the electronic device 101 may include a power control circuit (e.g., 750; 1150; 1351), a battery 189, a first capacitor bank (e.g., 761; 1161; 1361), a second capacitor bank (e.g., 762; 1162; 1362), a switch (e.g., 770; 1170; 1271, 1272, 1273, 1274; 1370), and a power amplifier (e.g., 780; 1180; 1381). The switch (e.g., 770; 1170; 1271, 1272, 1273, 1274; 1370) may be configured to selectively connect the battery 189 to the first capacitor bank (e.g., 761; 1161; 1361). The switches (e.g., 770; 1170; 1271, 1272, 1273, 1274; 1370) may be configured to selectively connect the power control circuit 750; 1150; 1351 to the first capacitor bank 761; 1161; 1361. The switch (e.g., 770; 1170; 1271, 1272, 1273, 1274; 1370) may be configured to selectively connect the power control circuit 750; 1150; 1351 to the second capacitor bank 762; 1162; 1362. The power amplifier 780; 1180; 1381 may be configured to receive a supply voltage based on power provided from the power control circuit 750; 1150; 1351, and amplify an RF signal based on the supply voltage.

According to an embodiment, in operation 601, the electronic device 101 may perform Tx transmission to the outside. Tx transmission may be an operation of transmitting an RF signal. For example, the electronic device 101 may amplify the RF signal based on the supply voltage provided to the power amplifier 780, 1180, 1381, 1382, thereby performing Tx transmission. For example, the electronic device 101 may identify the magnitude of the supply voltage VCC provided from the power control circuits 750; 1150; 1351. The electronic device 101 may identify a range of a voltage including the identified supply voltage. The electronic device 101 may identify a reference voltage range (or a reference range (e.g., a current reference range)) based on the range of the voltage including the supply voltage. A specific reference range may be set corresponding to a specific capacitor bank. The electronic device 101 may perform Tx transmission in a state in which the power control circuit 750; 1150; 1351 is connected to the capacitor bank corresponding to the identified reference range.

According to an embodiment, in operation 603, the electronic device 101 may identify whether the supply voltage VCC provided from the power control circuit 750; 1150; 1351 is included in a reference range (e.g., a new reference range) causing a change in the capacitor filter. For example, the electronic device 101 may identify the magnitude of the supply voltage provided from the power control circuit 750; 1150; 1351 and may identify whether the identified supply voltage falls within a reference range causing a change in the capacitor filter. The “reference range causing the change in the capacitor filter” may be a new reference range different from the current (or existing) reference range. The current (or existing) reference range may be a reference range corresponding to a capacitor bank currently connected to the power control circuit 750; 1150; 1351. The new reference range may be a reference range corresponding to a capacitor bank different from the capacitor bank currently connected to the power control circuit 750; 1150; 1351. For example, in operation 603, when the supply voltage is included in the reference range (or the reference voltage range), the supply voltage may be included in the new reference range. For example, in operation 603, when the supply voltage is not included in the reference range (or the reference voltage range), the supply voltage may not be included in the new reference range. For example, in operation 603, when the supply voltage is not included in the reference range (or the reference voltage range), the supply voltage may be included in the existing reference range. According to an embodiment, the operation of identifying whether the supply voltage VCC is included in the reference range may include the operation of identifying whether the supply voltage VCC is larger than or equal to (or exceeds) the first reference voltage. According to an embodiment, the operation of identifying whether the supply voltage VCC is included in the reference range may include the operation of identifying whether the supply voltage VCC is less than or equal to (or less than) the second reference voltage. According to an embodiment, the operation of identifying whether the supply voltage VCC is included in the reference range may include the operation of identifying whether the supply voltage VCC exceeds the third reference voltage and is less than or equal to the fourth reference voltage. According to an embodiment, the operation of identifying whether the supply voltage VCC is included in the reference range may include the operation of identifying whether the variation in the supply voltage VCC exceeds (or is larger than or equal to) the first reference amount. According to an embodiment, the operation of identifying whether the supply voltage VCC is included in the reference range may include the operation of identifying whether the variation in the supply voltage VCC is less than (or less than or equal to) the second reference amount. A detailed embodiment of the operation of identifying whether the supply voltage VCC is included in the reference range is described with reference to the drawings described below.

According to an embodiment, in operation 605, the electronic device 101 may maintain the existing capacitor filter based on the supply voltage VCC being not included in the new reference voltage range (or reference range). “Maintaining the existing capacitor filter” may be maintaining the connection with the capacitor bank currently connected to the power control circuit 750; 1150; 1351.

According to an embodiment, in operation 607, the electronic device 101 may change the capacitor filter based on the supply voltage VCC being included in the new reference voltage range (or reference range). “Changing the capacitor filter” may be disconnecting from the capacitor bank currently connected to the power control circuit 750; 1150; 1351 and connecting the power control circuit 750; 1150; 1351 to a new capacitor bank.

According to an embodiment, the electronic device 101 may change Tx transmission power (e.g., output power) after operation 605 or 607. For example, the electronic device 101 may change the Tx transmission power based on the operating frequency band. As the Tx transmission power is changed, operation 603 may be performed. According to an embodiment, the supply voltage VCC according to the Tx transmission power (e.g., output power) may be set. For example, the supply voltage VCC may be matched for each output power. According to an embodiment, the supply voltage VCC for each band/modulation may vary. According to an embodiment, the electronic device 101 may store a setting value of the supply voltage VCC corresponding to each output power, and may select a capacitor filter corresponding to the output power, thereby reducing or eliminating audio noise by minimizing the amount of charge and discharge that causes the capacitor shaking.

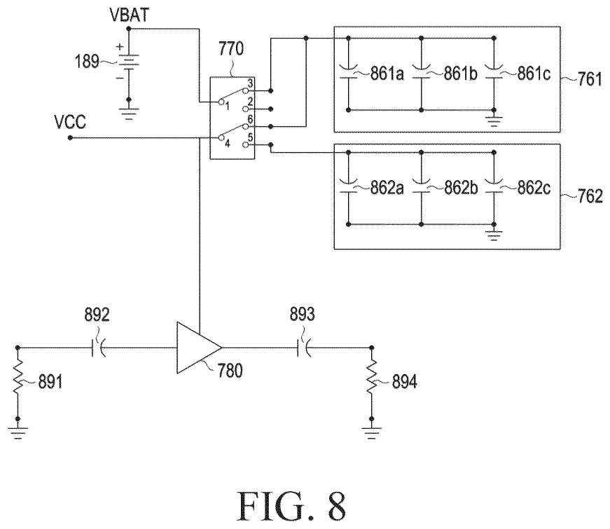

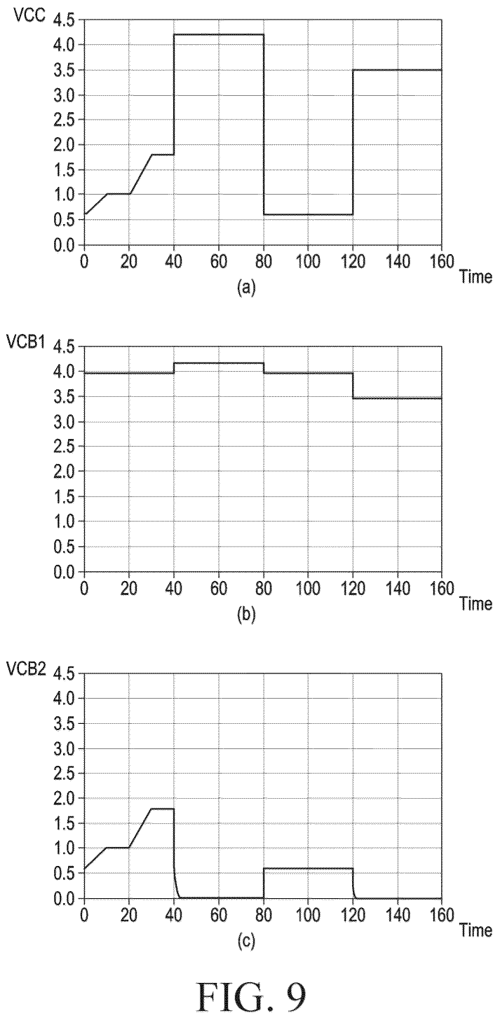

FIG. 7 is a view illustrating connection between components of an electronic device according to an embodiment. FIG. 8 is a circuit diagram illustrating an electronic device according to an embodiment. FIG. 9 is a graph illustrating a voltage applied to a capacitor bank connected to a power amplifier according to an embodiment.

The embodiment of FIG. 6 is described in detail with reference to the embodiments of FIGS. 7, 8, and 9. FIG. 8 is an exemplary circuit diagram corresponding to FIG. 7, but the circuit diagram corresponding to FIG. 7 is not limited to the embodiment of FIG. 8.

Referring to FIG. 7, the electronic device 101 may include a power control circuit 750, a battery 189, a switch 770, a first capacitor bank 761, a second capacitor bank 762, and a power amplifier 780. The power control circuit 750 may be the power control circuit 350 of FIG. 3. The power amplifier 780 may be the power amplifier 380 of FIG. 3. The power amplifier 780 may output the output signal Sig_out by amplifying the input signal Sig_in based on the supply power VCC provided from the power control circuit 750. Referring to FIG. 8, a resistor 891 and a capacitor 892 may be connected to an input terminal of the power amplifier 780, and a resistor 894 and a capacitor 893 may be connected to an output terminal of the power amplifier 780. The switch 770 may include a plurality of nodes 790. Components of the electronic device 101 may be electrically connected to the plurality of nodes of the switch 770. According to the operation of the switch 770, the plurality of nodes of the switch 770 may be electrically connected to each other, and thus the components of the electronic device 101 may be electrically connected to each other. Hereinafter, electrically connecting the components of the electronic device 101 may be electrically connecting nodes corresponding to the components of the electronic device 101 among the plurality of nodes of the switch 770 according to the operation of the switch 770.

Referring to FIG. 8, the first capacitor bank 761 may include a plurality of capacitors (e.g., 861a, 861b, and 861c). FIG. 8 illustrates that the first capacitor bank 761 includes three capacitors (e.g., 861a, 861b, and 861c), but this is merely an example, and the number of the plurality of capacitors included in the first capacitor bank 761 is not limited. The second capacitor bank 762 may include a plurality of capacitors (e.g., 862a, 862b, and 862c). FIG. 8 illustrates that the second capacitor bank 762 includes three capacitors (e.g., 862a, 862b, and 862c), but this is merely an example, and the number of the plurality of capacitors included in the second capacitor bank 762 is not limited.

Referring to FIG. 7, the switch 770 may be configured to selectively connect the battery 189 to the first capacitor bank 761. For example, referring to FIG. 8, the switch 770 may connect the battery 189 to the first capacitor bank 761 (e.g., by connecting nodes 1 and 3 in 770 of FIG. 8) or may not connect the battery 189 to the first capacitor bank 761 (e.g., by connecting nodes 1 and 2 in 770 of FIG. 8). Referring to FIG. 7, the switch 770 may be configured to selectively connect the power control circuit 750 to the first capacitor bank 761. The switch 770 may be configured to selectively connect the power control circuit 750 to the second capacitor bank 762. For example, the switch 770 may be configured to selectively connect the power control circuit 750 to the first capacitor bank 761 or the second capacitor bank 762. For example, referring to FIG. 8, the switch 770 may connect the power control circuit 750 to the first capacitor bank 761 (e.g., by connecting nodes 4 and 6 in 770 of FIG. 8), or may connect the power control circuit 750 to the second capacitor bank 762 (e.g., by connecting nodes 4 and 5 in 770 of FIG. 8).

Tx transmission in operation 601 of FIG. 6 is described below with reference to the embodiments of FIGS. 7 and 8. The electronic device 101 may control the switch 770 to connect the battery 189 to the first capacitor bank 761. The electronic device 101 may control the switch 770 to connect the power control circuit 750 and the second capacitor bank 762. The electronic device 101 may amplify the signal through the power amplifier 780 using the supply voltage VCC provided from the power control circuit 750 in a state in which the battery 189 and the first capacitor bank 761 are connected and the power control circuit 750 and the second capacitor bank 762 are connected. In this case, the supply voltage VCC provided from the power control circuit 750 may be included in a reference range (e.g., a first reference range) corresponding to the second capacitor bank 762 connected to the power control circuit 750. For example, the reference range (e.g., the first reference range) corresponding to the second capacitor bank 762 may be a range including voltages less than the reference voltage. In the embodiment of FIGS. 7 and 8, the “reference voltage” may be determined based on a set value of the supply voltage. For example, when the setting value of the supply voltage VCC provided from the power control circuit 750 is set from the first voltage (e.g., 0.6 [V]) to the second voltage (e.g., 4.5 [V]), the reference voltage may be determined to be half (e.g., 2.55 [V]) of the value obtained by subtracting the first voltage from the second voltage, but it will be understood by one of ordinary skill in the art that the method of determining the reference voltage is not limited. For example, in the embodiments of FIGS. 7 and 8, when the reference voltage is determined to be 2.55 [V], the reference range (e.g., the first reference range) corresponding to the second capacitor bank 762 may be a range including voltages having a reference voltage less than 2.55 [V], but it will be understood by one of ordinary skill in the art that this is an exemplary value. According to an embodiment, in the embodiment of comparing the variation in the supply voltage VCC with a reference amount, the reference range (e.g., the first reference range) corresponding to the second capacitor bank 762 in the embodiments of FIGS. 7 and 8 may be a range in which the variation in the supply voltage VCC is less than the reference amount. For example, when the setting value of the supply voltage VCC provided from the power control circuit 750 is set from the first voltage (e.g., 0.6 [V]) to the second voltage (e.g., 4.5 [V]), the reference amount may be determined as a value (e.g., 1.95 [V]) obtained by subtracting the first voltage (e.g., 0.6 [V]) from half (e.g., 2.55 [V]) of the value obtained by subtracting the first voltage from the second voltage, but it will be understood by one of ordinary skill in the art that the method of determining the reference amount is not limited. For example, in the embodiments of FIGS. 7 and 8, when the reference amount is determined to be 1.95 [V], the reference range (e.g., the first reference range) corresponding to the second capacitor bank 762 may be a range in which the variation in the supply voltage VCC is less than the reference amount of 1.95 [V], but it will be understood by one of ordinary skill in the art that this is an exemplary value.

Operation 603 of FIG. 6 is described below with reference to the embodiments of FIGS. 7 and 8. While the electronic device 101 performs Tx transmission, the supply voltage VCC provided from the power control circuit 750 may vary. For example, the electronic device 101 may identify the magnitude of the supply voltage VCC provided from the power control circuit 750. The electronic device 101 may identify whether the identified supply voltage is included in the new reference range (e.g., the second reference range). The new reference range (e.g., the second reference range) may be a voltage range corresponding to the first capacitor bank 761. For example, the reference range (e.g., the second reference range) corresponding to the first capacitor bank 761 may be a range including voltages equal to or larger than the reference voltage. For example, when the setting value of the supply voltage VCC provided from the power control circuit 750 is set from the first voltage (e.g., 0.6 [V]) to the second voltage (e.g., 4.5 [V]), the reference voltage may be determined to be half (e.g., 2.55 [V]) of the value obtained by subtracting the first voltage from the second voltage, but it will be understood by one of ordinary skill in the art that the method of determining the reference voltage is not limited. For example, in the embodiments of FIGS. 7 and 8, when the reference voltage is determined to be 2.55 [V], the reference range (e.g., the second reference range) corresponding to the first capacitor bank 761 may be a range including voltages having a reference voltage of 2.55 [V] or more, but it will be understood by one of ordinary skill in the art that this is an exemplary value. According to an embodiment, in the embodiment of comparing the variation in the supply voltage VCC with the reference amount, in the embodiments of FIGS. 7 and 8, the electronic device 101 may identify the variation in the supply voltage VCC provided from the power control circuit 750. The electronic device 101 may identify whether the identified variation exceeds the reference amount. For example, the electronic device 101 may determine to change or maintain the capacitor filter by identifying the variation in the supply voltage VCC and comparing the identified variation with the reference amount. For example, the electronic device 101 may maintain the existing capacitor filter based on the variation in the supply voltage VCC being less than the reference amount. For example, the electronic device 101 may change the capacitor filter based on the variation in the supply voltage VCC being larger than or equal to the reference amount.

Operation 605 of FIG. 6 is described below with reference to the embodiments of FIGS. 7 and 8. The electronic device 101 may maintain the existing capacitor filter based on the identified supply voltage not being included in the new reference range (e.g., the second reference range corresponding to the first capacitor bank 761) (i.e., based on the identified supply voltage being included in the existing reference range (e.g., the first reference range corresponding to the second capacitor bank 762)). Maintaining the existing capacitor filter based on the first reference range may be maintaining the state in which the power control circuit 750 and the second capacitor bank 762 are connected and the battery 189 and the first capacitor bank 761 are connected. According to an embodiment, in the embodiment of comparing the variation in the supply voltage VCC with the reference amount, in the embodiment of FIGS. 7 and 8, the electronic device 101 may maintain the existing capacitor filter (e.g., the second capacitor bank 762) based on the variation in the supply voltage VCC being less than the reference amount.

Operation 607 of FIG. 6 is described below with reference to the embodiments of FIGS. 7 and 8. The electronic device 101 may change the capacitor filter based on the identified supply voltage being included in the new reference range (e.g., the second reference range corresponding to the first capacitor bank 761). Changing the capacitor filter based on the second reference range may be disconnecting the battery 189 and the first capacitor bank 761, disconnecting the power control circuit 750 and the second capacitor bank 762, and connecting the power control circuit 750 and the first capacitor bank 761. According to an embodiment, in the embodiment of comparing the variation in the supply voltage VCC with the reference amount, in the embodiment of FIGS. 7 and 8, the electronic device 101 may change the capacitor filter (e.g., change to the first capacitor bank 761) based on the variation in the supply voltage VCC being larger than or equal to the reference amount.

Thereafter, the electronic device 101 may perform operation 603 again, and may change the capacitor filter based on the supply voltage being included in the new reference range (e.g., the first reference range corresponding to the second capacitor bank 762), or may maintain the capacitor filter based on the supply voltage being included in the existing reference range (e.g., the second reference range corresponding to the first capacitor bank 761). For example, maintaining the capacitor filter based on the second reference range corresponding to the first capacitor bank 761 may be maintaining the state in which the power control circuit 750 and the first capacitor bank 761 are connected. For example, changing the capacitor filter based on the first reference range corresponding to the second capacitor bank 762 may be disconnecting the power control circuit 750 and the first capacitor bank 761, connecting the power control circuit 750 and the second capacitor bank 762, and connecting the battery 189 and the first capacitor bank 761. According to an embodiment, in the embodiment of comparing the variation in the supply voltage VCC with the reference amount, in the embodiment of FIGS. 7 and 8, the electronic device 101 may identify the variation in the supply voltage VCC and may determine to change (e.g., change to the second capacitor bank 762) or maintain (e.g., maintain the first capacitor bank 761) the capacitor filter by comparing the identified variation with the reference amount.

FIG. 9 illustrates graphs of a supply voltage VCC, a first voltage VCB1 corresponding to a first capacitor bank 761, and a second voltage VCB2 corresponding to a second capacitor bank 762 according to the embodiments of FIGS. 7 and 8.

Referring to FIG. 9, it may be identified that the swing width (e.g., the difference between the maximum voltage and the minimum voltage) of the first voltage VCB1 corresponding to the first capacitor bank 761 and the swing width of the second voltage VCB2 corresponding to the second capacitor bank 762 are smaller than the swing width of the supply voltage VCC. For example, in FIG. 9, (a) may show the supply voltage VCC, (b) may show the first voltage VCB1 corresponding to the first capacitor bank 761, and (c) may show the second voltage VCB2 corresponding to the second capacitor bank 762. In FIG. 9, the supply voltage VCC may swing from 0.6 [V] to 4.2 [V] by 3.6 [V], but the first voltage VCB1 may swing from 3.5 [V] to 4.2 [V] by 0.7 [V], and the second voltage VCB2 may swing from 0 [V] to 1.6 [V] by 1.6 [V]. As a result, since the swing width of the first voltage VCB1 and the swing width of the second voltage VCB2 are smaller than the swing width of the supply voltage VCC, noise due to charging and discharging of the capacitor may be reduced.

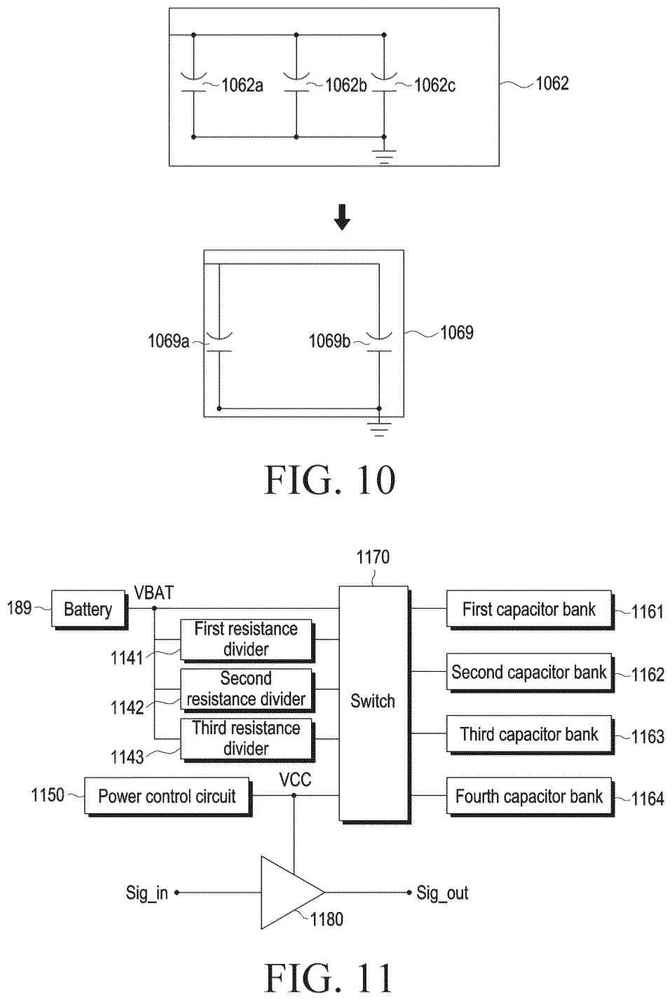

FIG. 10 is a view illustrating a replacement of a capacitor bank according to an embodiment.

The replacement of the capacitor bank of the embodiments of FIGS. 7 and 8 is described with reference to FIG. 10. The following description may be similarly applied to the replacement of the capacitor bank of the embodiment of FIG. 11 or the replacement of the capacitor bank of the embodiment of FIG. 13, and the description of FIGS. 11 and 13 is omitted. Here, the term “replacement” is used, but this is for convenience of description, and the capacitor bank may be implemented from the beginning as in the embodiment of FIG. 10 when the electronic device 101 is manufactured.

The replacement of the capacitor bank is described with reference to FIG. 10, and how the capacitor bank may be replaced is described with reference to FIG. 7. It is understood by one of ordinary skill in the art that the number of capacitors (e.g., 1062a, 1062b, 1062c, 1069a, and 1069b) included in the capacitor bank (e.g., 1062, 1069) in FIG. 10 is exemplary. According to an embodiment, a capacitor (or capacitor bank) having a low operating voltage may be replaced with a capacitor (or capacitor bank) having a lower capacitor value. For example, in FIG. 10, the capacitor bank 1062 including the first capacitor 1062a, the second capacitor 1062b, and the third capacitor 1062c may be replaced with the capacitor bank 1069 including the fourth capacitor 1069a and the fifth capacitor 1069b. In this case, the capacitance of the capacitor bank 1069 including the fourth capacitor 1069a and the fifth capacitor 1069b may be smaller than the capacitance of the capacitor bank 1062 including the first capacitor 1062a, the second capacitor 1062b, and the third capacitor 1062c. For example, the capacitance of the first capacitor 1062a may be 100 [pF], the capacitance of the second capacitor 1062b may be 2.2 [uF], the capacitance of the third capacitor 1062c may be 1 [uF], the capacitance of the fourth capacitor 1069a may be 100 [pF], and the capacitance of the fifth capacitor 1069b may be 1 [nF].

For example, referring to FIGS. 7 and 9, the minimum value of the first voltage VCB1 corresponding to the first capacitor bank 761 may be larger than or equal to the maximum value of the second voltage VCB2 corresponding to the second capacitor bank 762. In other words, the operating voltage of the first capacitor bank 761 and the operating voltage of the second capacitor bank 762 may be different. As a result, the second capacitor bank 762 may be implemented as a capacitor bank having a capacitance smaller than that of the first capacitor bank 761. In summary, the first capacitor bank 761 and the second capacitor bank 762 may be configured in the same manner, and thus may have the same capacitance. However, since the second capacitor bank 762 is implemented as a capacitor bank having a capacitance smaller than that of the first capacitor bank 761, the first capacitor bank 761 and the second capacitor bank 762 may be configured differently. In other words, the capacitance of the second capacitor bank 762 may be less than the capacitance of the first capacitor bank 761. Likewise, in the embodiment of FIG. 11 or the embodiment of FIG. 13, which is described below, capacitor banks having different operating voltages among the plurality of capacitor banks may be implemented to have different capacitances.

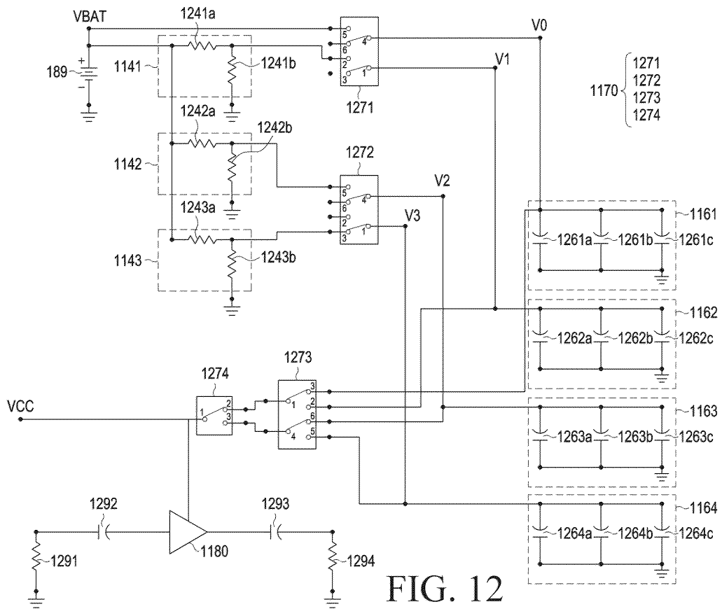

FIG. 11 is a view illustrating connection between components of an electronic device according to an embodiment. FIG. 12 is a circuit diagram illustrating an electronic device according to an embodiment.

The embodiment of FIG. 6 is described in detail with reference to the embodiments of FIGS. 11, and 12. FIG. 12 is an exemplary circuit diagram corresponding to FIG. 11, but the circuit diagram corresponding to FIG. 11 is not limited to the embodiment of FIG. 12.

Referring to FIG. 11, an electronic device 101 may include a power control circuit 1150, a battery 189, a switch 1170, a first capacitor bank 1161, a second capacitor bank 1162, a third capacitor bank 1163, a fourth capacitor bank 1164, a first resistance divider 1141, a second resistance divider 1142, a third resistance divider 1143, and a power amplifier 1180. The first resistance divider 1141 may be electrically connected to the battery 189. The second resistance divider 1142 may be electrically connected to the battery 189. The third resistance divider 1143 may be electrically connected to the battery 189. The power control circuit 1150 may be the power control circuit 350 of FIG. 3. The power amplifier 1180 may be the power amplifier 380 of FIG. 3. The power amplifier 1180 may output the output signal Sig_out by amplifying the input signal Sig_in based on the supply power VCC provided from the power control circuit 1150. Referring to FIG. 12, a resistor 1291 and a capacitor 1292 may be connected to an input terminal of the power amplifier 1180, and a resistor 1294 and a capacitor 1293 may be connected to an output terminal of the power amplifier 1180. The switch 1170 may include a plurality of nodes. Components of the electronic device 101 may be electrically connected to the plurality of nodes of the switch 1170. According to the operation of the switch 1170, the plurality of nodes of the switch 1170 may be electrically connected to each other, and thus the components of the electronic device 101 may be electrically connected to each other. Hereinafter, electrically connecting the components of the electronic device 101 may be electrically connecting nodes corresponding to the components of the electronic device 101 among the plurality of nodes of the switch 1170 according to the operation of the switch 1170.

Referring to FIG. 12, the first capacitor bank 1161 may include a plurality of capacitors (e.g., 1261a, 1261b, and 1261c). FIG. 12 illustrates that the first capacitor bank 1161 includes three capacitors (e.g., 1261a, 1261b, and 1261c), but this is merely an example, and the number of the plurality of capacitors included in the first capacitor bank 1161 is not limited. The second capacitor bank 1162 may include a plurality of capacitors (e.g., 1262a, 1262b, and 1262c). FIG. 12 illustrates that the second capacitor bank 1162 includes three capacitors (e.g., 1262a, 1262b, and 1262c), but this is merely an example, and the number of the plurality of capacitors included in the second capacitor bank 1162 is not limited. The third capacitor bank 1163 may include a plurality of capacitors (e.g., 1263a, 1263b, and 1263c). FIG. 12 illustrates that the third capacitor bank 1163 includes three capacitors (e.g., 1263a, 1263b, and 1263c), but this is merely an example, and the number of the plurality of capacitors included in the third capacitor bank 1163 is not limited. The fourth capacitor bank 1164 may include a plurality of capacitors (e.g., 1264a, 1264b, and 1264c). FIG. 12 illustrates that the fourth capacitor bank 1164 includes three capacitors (e.g., 1264a, 1264b, and 1264c), but this is merely an example, and the number of the plurality of capacitors included in the fourth capacitor bank 1164 is not limited. As described above with reference to FIG. 10, the first capacitor bank 1161, the second capacitor bank 1162, the third capacitor bank 1163, and the fourth capacitor bank 1164 may be implemented to have the same capacitance or may be implemented to have different capacitances depending on the operating voltage.

Referring to FIG. 12, the switch 1170 may include a first switch 1271, a second switch 1272, a third switch 1273, and a fourth switch 1274, but the configuration of the switch 1170 is not limited to the embodiment of FIG. 12. The plurality of nodes of the switch 1170 may include the plurality of nodes of the first switch 1271, the plurality of nodes of the second switch 1272, the plurality of nodes of the third switch 1273, and the plurality of nodes of the fourth switch 1274.

Referring to FIG. 11, the switch 1170 may be configured to selectively connect the first capacitor bank 1161 to the battery 189. For example, referring to FIG. 12, the switch 1170 (e.g., the first switch 1271) may connect the first capacitor bank 1161 to the battery 189 (e.g., by connecting nodes 4 and 5 in 1271 of FIG. 12), or may not connect the first capacitor bank 1161 to the battery 189 (e.g., by connecting nodes 4 and 6 in 1271 of FIG. 12). When the first capacitor bank 1161 is connected to the battery 189, the voltage V0 of the first capacitor bank 1161 may correspond to the voltage V BAT of the battery 189.

Referring to FIG. 11, the switch 1170 may be configured to selectively connect the second capacitor bank 1162 to the first resistance divider 1141. For example, referring to FIG. 12, the switch 1170 (e.g., the first switch 1271) may not connect the second capacitor bank 1162 to the first resistance divider 1141 (e.g., by connecting nodes 1 and 2 in 1271 of FIG. 12), or may not connect the second capacitor bank 1162 to the first resistance divider 1141 (e.g., by connecting nodes 1 and 3 in 1271 of FIG. 12). Referring to FIG. 12, the first resistance divider 1141 may include a first resistor 1241a and a second resistor 1241b, but the configuration of the resistors included in the first resistance divider 1141 is not limited thereto. For example, the second capacitor bank 1162 may be connected in parallel to the second resistor 1241b based on the operation of the switch 1170 (e.g., by connecting nodes 1 and 2 in the first switch 1271). When the second capacitor bank 1162 and the first resistance divider 1141 are connected, the voltage V1 of the second capacitor bank 1162 may correspond to the voltage of the second resistor 1241b of the first resistance divider 1141. The voltage of the second resistor 1241b may be determined according to a resistance ratio of the first resistor 1241a and the second resistor 1241b.

Referring to FIG. 11, the switch 1170 may be configured to selectively connect the third capacitor bank 1163 to the second resistance divider 1142. For example, referring to FIG. 12, the switch 1170 (e.g., the second switch 1272) may connect the third capacitor bank 1163 to the second resistance divider 1142 (e.g., by connecting nodes 4 and 5 in 1272 of FIG. 12), or may not connect the third capacitor bank 1163 to the second resistance divider 1142 (e.g., by connecting nodes 4 and 6 in 1272 of FIG. 12). Referring to FIG. 12, the second resistance divider 1142 may include a third resistor 1242a and a fourth resistor 1242b, but the configuration of the resistors included in the second resistance divider 1142 is not limited thereto. For example, the third capacitor bank 1163 may be connected in parallel to the fourth resistor 1242b based on the operation of the switch 1170 (e.g., by connecting nodes 4 and 5 in the second switch 1272). When the third capacitor bank 1163 and the second resistance divider 1142 are connected, the voltage V2 of the third capacitor bank 1163 may correspond to the voltage of the fourth resistor 1242b of the second resistance divider 1142. The voltage of the fourth resistor 1242b may be determined according to a resistance ratio of the third resistor 1242a and the fourth resistor 1242b.

Referring to FIG. 11, the switch 1170 may be configured to selectively connect the fourth capacitor bank 1164 to the third resistance divider 1143. For example, referring to FIG. 12, the switch 1170 (e.g., the second switch 1272) may not connect the fourth capacitor bank 1164 to the third resistance divider 1143 (e.g., by connecting nodes 1 and 3 in 1272 of FIG. 12), or may not connect the fourth capacitor bank 1164 to the third resistance divider 1143 (e.g., by connecting nodes 1 and 2 in 1272 of FIG. 12). Referring to FIG. 12, the third resistance divider 1143 may include a fifth resistor 1243a and a sixth resistor 1243b, but the configuration of the resistors included in the third resistance divider 1143 is not limited thereto. For example, the fourth capacitor bank 1164 may be connected in parallel to the sixth resistor 1243b based on the operation of the switch 1170 (e.g., by connecting nodes 1 and 3 in the second switch 1272). When the fourth capacitor bank 1164 and the third resistance divider 1143 are connected, the voltage V3 of the fourth capacitor bank 1164 may correspond to the voltage of the sixth resistor 1243b of the third resistance divider 1143. The voltage of the sixth resistor 1243b may be determined according to a resistance ratio of the fifth resistor 1243a and the sixth resistor 1243b.

Referring to FIG. 11, the switch 1170 may be configured to selectively connect the first capacitor bank 1161 to the power control circuit 1150. For example, referring to FIG. 12, the switch 1170 (e.g., the third switch 1273 and the fourth switch 1274) may connect the first capacitor bank 1161 to the power control circuit 1150 (e.g., by connecting nodes 1 and 3 in 1273 of FIG. 12 and connecting 1 and 2 in 1274). When the switch 1170 (e.g., the third switch 1273 and the fourth switch 1274) is connected differently, the first capacitor bank 1161 may not be connected to the power control circuit 1150.

Referring to FIG. 11, the switch 1170 may be configured to selectively connect the second capacitor bank 1162 to the power control circuit 1150. For example, referring to FIG. 12, the switch 1170 (e.g., the third switch 1273 and the fourth switch 1274) may connect the second capacitor bank 1162 to the power control circuit 1150 (e.g., by connecting nodes 1 and 2 in 1273 of FIG. 12 and connecting 1 and 2 in 1274). When the switch 1170 (e.g., the third switch 1273 and the fourth switch 1274) is connected differently, the second capacitor bank 1162 may not be connected to the power control circuit 1150.

Referring to FIG. 11, the switch 1170 may be configured to selectively connect the third capacitor bank 1163 to the power control circuit 1150. For example, referring to FIG. 12, the switch 1170 (e.g., the third switch 1273 and the fourth switch 1274) may connect the third capacitor bank 1163 to the power control circuit 1150 (e.g., by connecting nodes 4 and 6 in 1273 of FIG. 12 and connecting 1 and 3 in 1274). When the switch 1170 (e.g., the third switch 1273 and the fourth switch 1274) is connected differently, the third capacitor bank 1163 may not be connected to the power control circuit 1150.

Referring to FIG. 11, the switch 1170 may be configured to selectively connect the fourth capacitor bank 1164 to the power control circuit 1150. For example, referring to FIG. 12, the switch 1170 (e.g., the third switch 1273 and the fourth switch 1274) may connect the fourth capacitor bank 1164 to the power control circuit 1150 (e.g., by connecting nodes 4 and 5 in 1273 of FIG. 12 and connecting 1 and 3 in 1274). When the switch 1170 (e.g., the third switch 1273 and the fourth switch 1274) is connected differently, the fourth capacitor bank 1164 may not be connected to the power control circuit 1150.

Tx transmission in operation 601 of FIG. 6 is described below with reference to the embodiments of FIGS. 11 and 12. For example, the electronic device 101 may control the switch 770 to connect the battery 189 to the first capacitor bank 1161. The electronic device 101 may control the switch 770 to connect the first resistance divider 1141 and the second capacitor bank 1162. The electronic device 101 may control the switch 770 to connect the second resistance divider 1142 and the third capacitor bank 1163. The electronic device 101 may control the switch 770 to connect the power control circuit 1150 and the fourth capacitor bank 1164. The electronic device 101 may amplify the signal through the power amplifier 1180 using the supply voltage VCC provided from the power control circuit 1150 in a state in which the battery 189 and the first capacitor bank 1161 are connected, the first resistance divider 1141 and the second capacitor bank 1162 are connected, the second resistance divider 1142 and the third capacitor bank 1163 are connected, and the power control circuit 1150 and the fourth capacitor bank 1164 are connected. As compared to the embodiment of FIG. 7, according to the embodiment of FIGS. 11 and 12, the capacitor bank (e.g., 1161, 1162, 1163, 1164) may be extended. When the capacitor bank (e.g., 1161, 1162, 1163, 1164) is extended, the variable voltage (e.g., the reference amount of the variation in the supply voltage VCC) and the reference voltage, which are references for the change of the capacitor filter, may be changed according to the number of extensions of the capacitor filter. According to an embodiment, the swing width of the voltage of the capacitor filter may be reduced by adjusting the constant voltage value (e.g., V0, V1, V2, and V3 of FIG. 12) for each capacitor bank. According to an embodiment, noise may be reduced by reducing the variation in the voltage of the capacitor filter. For example, referring to FIGS. 11 and 12, a reference range (e.g., a first reference range) corresponding to the first capacitor bank 1161 may be a range including voltages equal to or larger than the first reference voltage V1. The first reference voltage may be the voltage of the second resistor 1241b of the first resistance divider 1141. The reference range (e.g., the second reference range) corresponding to the second capacitor bank 1162 may be a range in which voltages less than the first reference voltage V1 and larger than or equal to the second reference voltage V2 are included. The second reference voltage may be the voltage of the fourth resistor 1242b of the second resistance divider 1142. The reference range (e.g., the third reference range) corresponding to the third capacitor bank 1163 may be a range in which voltages less than the second reference voltage V2 and larger than or equal to the third reference voltage V3 are included. The third reference voltage may be the voltage of the sixth resistor 1243b of the third resistance divider 1143. The reference range (e.g., the fourth reference range) corresponding to the fourth capacitor bank 1164 may be a range including voltages less than the third reference voltage V3. Accordingly, in operation 601, the supply voltage VCC provided from the power control circuit 1150 may be included in a reference range (e.g., a fourth reference range) corresponding to the fourth capacitor bank 1164 connected to the power control circuit 1150. Hereinafter, an embodiment in which the supply voltage VCC is included in the reference range (e.g., the fourth reference range) corresponding to the fourth capacitor bank 1164 is described as the example, and with reference to this description, an embodiment in which the supply voltage VCC is not the reference range (e.g., the fourth reference range) corresponding to the fourth capacitor bank 1164, but the reference range (e.g., the first reference range) corresponding to the first capacitor bank 1161, the reference range (e.g., the second reference range) corresponding to the second capacitor bank 1162, or the reference range (e.g., the third reference range) corresponding to the third capacitor bank 1163 may also be understood.

Operation 603 of FIG. 6 is described below with reference to the embodiments of FIGS. 11 and 12. While the electronic device 101 performs Tx transmission, the supply voltage VCC provided from the power control circuit 750 may vary. The electronic device 101 may identify the magnitude of the supply voltage VCC provided from the power control circuit 750. The electronic device 101 may identify whether the identified supply voltage is included in the new reference range (e.g., the first reference range, the second reference range, or the third reference range).

Operation 605 of FIG. 6 is described below with reference to the embodiments of FIGS. 11 and 12. The electronic device 101 may maintain the existing capacitor filter based on the identified supply voltage not being included in the new reference range (e.g., the first reference range, the second reference range, or the third reference range) (i.e., based on the identified supply voltage being included in the existing reference range (e.g., the fourth reference range corresponding to the fourth capacitor bank 1164)). Maintaining the existing capacitor filter based on the fourth reference range may be maintaining the existing state of connecting the power control circuit 1150 and the fourth capacitor bank 1164, connecting the battery 189 and the first capacitor bank 1161, connecting the first resistance divider 1141 and the second capacitor bank 1162, and connecting the second resistance divider 1142 and the third capacitor bank 1163.

Operation 607 of FIG. 6 is described below with reference to the embodiments of FIGS. 11 and 12. The electronic device 101 may change the capacitor filter based on the identified supply voltage being included in the new reference range (e.g., the first reference range, the second reference range, or the third reference range). For example, changing the capacitor filter based on the first reference range may include disconnecting the battery 189 and the first capacitor bank 1161, disconnecting the power control circuit 1150 and the fourth capacitor bank 1164, connecting the power control circuit 1150 and the first capacitor bank 1161, connecting the third resistance divider 1143 and the fourth capacitor bank 1164, maintaining the connection between the first resistance divider 1141 and the second capacitor bank 1162, and maintaining the connection between the second resistance divider 1142 and the third capacitor bank 1163. For example, changing the capacitor filter based on the second reference range may include disconnecting the first resistance divider 1141 and the second capacitor bank 1162, disconnecting the power control circuit 1150 and the fourth capacitor bank 1164, connecting the power control circuit 1150 and the second capacitor bank 1162, connecting the third resistance divider 1143 and the fourth capacitor bank 1164, maintaining the connection between the battery 189 and the first capacitor bank 1161, and maintaining the connection between the second resistance divider 1142 and the third capacitor bank 1163. For example, changing the capacitor filter based on the third reference range may include disconnecting the second resistance divider 1142 and the third capacitor bank 1163, disconnecting the power control circuit 1150 and the fourth capacitor bank 1164, connecting the power control circuit 1150 and the third capacitor bank 1163, connecting the third resistance divider 1143 and the fourth capacitor bank 1164, maintaining the connection between the battery 189 and the first capacitor bank 1161, and maintaining the connection between the first resistance divider 1141 and the second capacitor bank 1162.

Thereafter, the electronic device 101 may perform operation 603 again, and may change the capacitor filter based on the supply voltage being included in the new reference range (e.g., the fourth reference range corresponding to the fourth capacitor bank 1164), or may maintain the capacitor filter based on the supply voltage being included in the existing reference range (e.g., the first reference range, the second reference range, or the third reference range). For example, changing the capacitor filter based on the fourth reference range corresponding to the fourth capacitor bank 1164 may include disconnecting from the capacitor bank (e.g., 1161, 1162, or 1163) connected to the power control circuit 750, connecting the power control circuit 750 and the fourth capacitor bank 1164, connecting the battery 189 and the first capacitor bank 1161, connecting the first resistance divider 1141 and the second capacitor bank 1162, and connecting the second resistance divider 1142 and the third capacitor bank 1163.

FIG. 13 is a view illustrating connection between components of an electronic device according to an embodiment.

The embodiment of FIG. 6 is described in detail with reference to the embodiment of FIG. 13.

Referring to FIG. 13, an electronic device 101 may include a first power control circuit 1351, a second power control circuit 1352, a battery 189, a switch 1370, a first capacitor bank 1361, a second capacitor bank 1362, a first power amplifier 1381, and a second power amplifier 1382. For example, the first capacitor bank 1361 may be electrically connected to the first power control circuit 1351 and the first power amplifier 1381. The second capacitor bank 1362 may be electrically connected to the second power control circuit 1352 and the second power amplifier 1382. For example, the first capacitor bank 1361 and the second capacitor bank 1362 may be disposed adjacent to each other. The first power control circuit 1351 and the second power control circuit 1352 may correspond to the power control circuit 350 of FIG. 3. The first power amplifier 1381 and the second power amplifier 1382 may correspond to the power amplifier 380 of FIG. 3. The first power amplifier 1381 may output the first output signal Sig1_out by amplifying the first input signal Sig1_in based on the first supply power VCC1 provided from the first power control circuit 1351. The second power amplifier 1382 may output the second output signal Sig2_out by amplifying the second input signal Sig2_in based on the second supply power VCC2 provided from the second power control circuit 1352. The switch 1370 may include a plurality of nodes. Components of the electronic device 101 may be electrically connected to the plurality of nodes of the switch 1370. According to the operation of the switch 1370, the plurality of nodes of the switch 1370 may be electrically connected to each other, and thus the components of the electronic device 101 may be electrically connected to each other. Hereinafter, electrically connecting the components of the electronic device 101 may be electrically connecting nodes corresponding to the components of the electronic device 101 among the plurality of nodes of the switch 1370 according to the operation of the switch 1370. The embodiment of FIG. 13 may exemplarily describe a case in which the first output signal Sig1_out is output by amplifying the first input signal Sig1_in based on the first supply power VCC1. In this case, the second supply power VCC2 may not be supplied or may be supplied.

According to an embodiment, the first capacitor bank 1361 may include a plurality of capacitors. The number of a plurality of capacitors included in the first capacitor bank 1361 is not limited. The second capacitor bank 1362 may include a plurality of capacitors. The number of the plurality of capacitors included in the second capacitor bank 1362 is not limited.

Referring to FIG. 13, the switch 1370 may be configured to selectively connect the battery 189 to the first capacitor bank 1361. The switch 1370 may be configured to selectively connect the battery 189 to the second capacitor bank 1362. For example, the switch 1370 may be configured to selectively connect the battery 189 to the first capacitor bank 1361, the second capacitor bank 1362, or an empty node 1390. The switch 1370 may be configured to selectively connect the first power control circuit 1351 to the first capacitor bank 1361. The switch 1370 may be configured to selectively connect the first power control circuit 1351 to the second capacitor bank 1362. For example, the switch 1370 may be configured to selectively connect the first power control circuit 1351 to the first capacitor bank 1361 or the second capacitor bank 1362. The switch 1370 may be configured to selectively connect the second power control circuit 1352 to the second capacitor bank 1362. The switch 1370 may be configured to selectively connect the second power control circuit 1352 to the first capacitor bank 1361. For example, the switch 1370 may be configured to selectively connect the first power control circuit 1351 to the first capacitor bank 1361 or the second capacitor bank 1362.

Referring to the embodiment of FIG. 13, Tx transmission of operation 601 of FIG. 6 is described as follows. The electronic device 101 may control the switch 1370 to connect the battery 189 and the second capacitor bank 1362. The electronic device 101 may control the switch 1370 to connect the first power control circuit 1351 and the first capacitor bank 1361. The electronic device 101 may amplify the signal through the first power amplifier 1381 using the first supply voltage VCC1 provided from the first power control circuit 1351 in a state in which the battery 189 and the second capacitor bank 1362 are connected and the first power control circuit 1351 and the first capacitor bank 1361 are connected. In this case, the first supply voltage VCC1 provided from the first power control circuit 1351 may be included in the reference range (e.g., the first reference range) corresponding to the first capacitor bank 1361 connected to the first power control circuit 1351. For example, the reference range (e.g., the first reference range) corresponding to the first capacitor bank 1361 may be a range including voltages less than the reference voltage. In the embodiment of FIG. 13, the “reference voltage” may be determined based on a first setting value of the first supply voltage VCC1. In other words, the first power control circuit 1351 may adjust the first supply voltage VCC1. For example, when the first setting value of the first supply voltage VCC1 provided from the first power control circuit 1351 is set from the first voltage (e.g., 0.6 [V]) to the second voltage (e.g., 4.5 [V]), the reference voltage may be determined to be half (e.g., 2.55 [V]) of the value obtained by subtracting the first voltage from the second voltage, but it will be understood by one of ordinary skill in the art that the method of determining the reference voltage is not limited. For example, in the embodiment of FIG. 13, when the reference voltage is determined to be 2.55 [V], the reference range (e.g., the first reference range) corresponding to the first capacitor bank 1361 may be a range including voltages less than a reference voltage of 2.55 [V], but it will be understood by one of ordinary skill in the art that this is an exemplary value. According to an embodiment, in the embodiment of comparing the variation in the supply voltage VCC with the reference amount, the reference range (e.g., the first reference range) corresponding to the first capacitor bank 1361 in the embodiment of FIG. 13 may be a range in which the variation in the supply voltage VCC is less than the reference amount. For example, when the first setting value of the first supply voltage VCC1 provided from the first power control circuit 1351 is set from the first voltage (e.g., 0.6 [V]) to the second voltage (e.g., 4.5 [V]), the reference amount may be determined as a value (e.g., 1.95 [V]) obtained by subtracting the first voltage (e.g., 0.6 [V]) from half (e.g., 2.55 [V]) of the value obtained by subtracting the first voltage from the second voltage, but it will be understood by one of ordinary skill in the art that the method of determining the reference amount is not limited. For example, in the embodiment of FIG. 13, when the reference amount is determined to be 1.95 [V], the reference range (e.g., the first reference range) corresponding to the first capacitor bank 1361 may be a range in which the variation in the supply voltage VCC is less than the reference amount of 1.95 [V], but it will be understood by one of ordinary skill in the art that this is an exemplary value.

Referring to the embodiment of FIG. 13, operation 603 of FIG. 6 is described as follows. While the electronic device 101 performs Tx transmission, the first supply voltage VCC1 provided from the first power control circuit 1351 may vary. The electronic device 101 may identify the magnitude of the first supply voltage VCC1 provided from the first power control circuit 1351. The electronic device 101 may identify whether the identified first supply voltage is included in the new reference range (e.g., the second reference range). The new reference range (e.g., the second reference range) may be a voltage range corresponding to the second capacitor bank 1362. For example, the reference range (e.g., the second reference range) corresponding to the second capacitor bank 1362 may be a range including voltages larger than or equal to the reference voltage. For example, when the first setting value of the first supply voltage VCC1 provided from the first power control circuit 1351 is set from the first voltage (e.g., 0.6 [V]) to the second voltage (e.g., 4.5 [V]), the reference voltage may be determined to be half (e.g., 2.55 [V]) of the value obtained by subtracting the first voltage from the second voltage, but it will be understood by one of ordinary skill in the art that the method of determining the reference voltage is not limited. For example, in the embodiment of FIG. 13, when the reference voltage is determined to be 2.55 [V], the reference range (e.g., the second reference range) corresponding to the second capacitor bank 1362 may be a range including voltages having a reference voltage of 2.55 [V] or more, but it will be understood by one of ordinary skill in the art that this is an exemplary value.

Referring to the embodiment of FIG. 13, operation 605 of FIG. 6 is described as follows. The electronic device 101 may maintain the existing capacitor filter based on the identified first supply voltage being not included in the new reference range (e.g., the second reference range corresponding to the second capacitor bank 1362) (i.e., based on the identified supply voltage being included in the existing reference range (e.g., the first reference range corresponding to the first capacitor bank 1361)). Maintaining the existing capacitor filter based on the first reference range may be maintaining a state in which the first power control circuit 1351 and the first capacitor bank 1361 are connected, and the battery 189 and the second capacitor bank 1362 are connected.

Referring to the embodiment of FIG. 13, operation 607 of FIG. 6 is described as follows. The electronic device 101 may change the capacitor filter based on the identified first supply voltage being included in the new reference range (e.g., the second reference range corresponding to the second capacitor bank 1362). Changing the capacitor filter based on the second reference range may be disconnecting the battery 189 and the second capacitor bank 1362, disconnecting the first power control circuit 1351 and the first capacitor bank 1361, and connecting the first power control circuit 1351 and the second capacitor bank 1362.

Thereafter, the electronic device 101 may perform operation 603 again, and may change the capacitor filter based on the first supply voltage being included in the new reference range (e.g., a first reference range corresponding to the first capacitor bank 1361), or may maintain the capacitor filter based on the first supply voltage being included in the existing reference range (e.g., the second reference range corresponding to the second capacitor bank 1362). For example, maintaining the capacitor filter based on the second reference range corresponding to the second capacitor bank 1362 may be maintaining the state in which the first power control circuit 1351 and the second capacitor bank 1362 are connected. For example, changing the capacitor filter based on the first reference range corresponding to the first capacitor bank 1361 may be disconnecting the first power control circuit 1351 and the second capacitor bank 1362, connecting the first power control circuit 1351 and the first capacitor bank 1361, and connecting the battery 189 and the second capacitor bank 1362.

It may be understood by one of ordinary skill in the art that embodiments described herein may be applied interchangeably within the applicable scope. For example, it will be understood by one of ordinary skill in the art that at least some operations of an embodiment described in the disclosure may be omitted and applied, or at least some operations of an embodiment may be applied in connection with each other.

Technical objects to be achieved herein are not limited to the foregoing technical objects, and other technical objects not mentioned may be clearly understood by those skilled in the art from the following description.

Effects obtainable from the disclosure are not limited to the above-mentioned effects, and other effects not mentioned may be clearly understood by those skilled in the art from the following description.

According to an embodiment, an electronic device 101 may comprise a first power control circuit 750; 1150; 1351 configured to supply a first supply voltage which is based on transmission power (e.g., output power); a first power amplifier 780; 1180; 1381 configured to amplify a first RF signal, based on the first supply voltage; a battery 189 configured to provide at least one reference voltage; a plurality of capacitor banks 761; 762; 1161; 1162; 1163; 1164; 1361; 1362 including a first capacitor bank 761; 1161; 1361 and a second capacitor bank 762; 1162; 1362; and a switch 770; 1170; 1271,1272,1273,1274; 1370 including a plurality of nodes and configured to selectively connect a node corresponding to one of the plurality of capacitor banks 761; 762; 1161; 1162; 1163; 1164; 1361; 1362, among the plurality of nodes, to a node corresponding to the first power control circuit 750; 1150; 1351, among the plurality of nodes, based on the first supply voltage. The switch 770; 1170; 1271,1272,1273,1274;1370 may be configured to, based on the first supply voltage being included in a first reference range, supply the first supply voltage to the first capacitor bank 761; 1161; 1361 by connecting the node corresponding to the first power control circuit 750; 1150; 1351 to a node corresponding to the first capacitor bank 761; 1161; 1361 among the plurality of nodes. The switch 770; 1170; 1271,1272,1273,1274; 1370 may be configured to, based on the first supply voltage being included in a second reference range, supply the first supply voltage to the second capacitor bank 762; 1162; 1362 by connecting the node corresponding to the first power control circuit 750; 1150; 1351 to a node corresponding to the second capacitor bank 762; 1162; 1362 among the plurality of nodes, and supply a first reference voltage to the first capacitor bank 761; 1161; 1361 by connecting a node corresponding to the battery 189, among the plurality of nodes, to the node corresponding to the first capacitor bank 761; 1161; 1361.

According to an embodiment, the electronic device 101 may comprise an antenna 242, 244, 246, 248. The first power amplifier 780, 1180, 1381 may be further configured to provide the amplified first RF signal to the antenna 242, 244, 246, 248 for communication between the electronic device 101 and an external device 102. The first power control circuit 750, 1150, 1351 is further configured to supply the first supply voltage which is based on a level of the transmission power (e.g., output power) for the communication. The first power control circuit 750; 1150; 1351 may adjust the first supply voltage based on the level of the output power for the communication.

According to an embodiment, the first reference range may comprise voltages greater than or equal to the first reference voltage. The second reference range may comprise voltages less than the first reference voltage.

According to an embodiment, a capacitance of the second capacitor bank 762 may be smaller than a capacitance of the first capacitor bank 761.

According to an embodiment, the electronic device 101 may comprise a first resistance divider 1141; 1241a,1241b electrically connected to the battery 189, a second resistance divider 1142; 1242a,1242b electrically connected to the battery 189, and a third resistance divider 1143; 1243a,1243b electrically connected to the battery 189. The plurality of capacitor banks 761; 762; 1161; 1162; 1163; 1164; 1361; 1362 may include a third capacitor bank 1163 and a fourth capacitor bank 1164. The switch 1170; 1271,1272,1273,1274 may be configured to selectively connect the node corresponding to the second capacitor bank 1162 to a node corresponding to the first resistance divider 1141; 1241a, 1241b, among the plurality of nodes. The switch 1170; 1271,1272,1273,1274 may be configured to selectively connect a node corresponding to the third capacitor bank 1163, among the plurality of nodes, to a node corresponding to the second resistance divider 1142; 1242a, 1242b, among the plurality of nodes. The switch 1170; 1271,1272,1273,1274 may be configured to selectively connect a node corresponding to the fourth capacitor bank 1164, among the plurality of nodes, to a node corresponding to the third resistance divider 1143; 1243a, 1243b, among the plurality of nodes.

According to an embodiment, the first reference range may comprise voltages greater than or equal to the first reference voltage. The second reference range may comprise voltages less than the first reference voltage and greater than or equal to a second reference voltage. The third reference range may comprise voltages less than the second reference voltage and greater than or equal to a third reference voltage. The fourth reference range may comprise voltages less than the third reference voltage. The switch 1170; 1271,1272,1273,1274 may be configured to, based on the first supply voltage being included in the first reference range, supplying the first supply voltage to the first capacitor bank 1161 by connecting the node corresponding to the first capacitor bank 1161 to the node corresponding to the first power control circuit 1150, supplying the second reference voltage to the second capacitor bank 1162 by connecting the node corresponding to the second capacitor bank 1162 to the node corresponding to the first resistance divider 1141; 1241a,1241b, supplying the third reference voltage to the third capacitor bank 1163 by connecting the node corresponding to the third capacitor bank 1163 to the node corresponding to the second resistance divider 1142; 1242a,1242b, and supplying a fourth reference voltage to the fourth capacitor bank 1164 by connecting the node corresponding to the fourth capacitor bank 1164 to the node corresponding to the third resistance divider 1143; 1243a,1243b. The switch 1170; 1271,1272,1273,1274 may be configured to, based on the first supply voltage being included in the second reference range, supply the first reference voltage to the first capacitor bank 761; 1161; 1361 by connecting the node corresponding to the first capacitor bank 1161 to the node corresponding to the battery 189, supplying the first supply voltage to the second capacitor bank 1162 by connecting the node corresponding to the second capacitor bank 1162 to the node corresponding to the first power control circuit 1150, supply the third reference voltage to the third capacitor bank 1163 by connecting the node corresponding to the third capacitor bank 1163 to the node corresponding to the second resistance divider 1142; 1242a,1242b, and supplying the fourth reference voltage to the fourth capacitor bank 1164 by connecting the node corresponding to the fourth capacitor bank 1164 to the node corresponding to the third resistance divider 1143; 1243a,1243b, The switch 1170; 1271,1272,1273,1274 may be configured to, based on the first supply voltage being included in the third reference range, supply the first reference voltage to the first capacitor bank 1161 by connecting the node corresponding to the first capacitor bank 1161 to the node corresponding to the battery 189, supply the second reference voltage to the second capacitor bank 1162 by connecting the node corresponding to the second capacitor bank 1162 to the node corresponding to the first resistance divider 1141; 1241a,1241b, supplying the first supply voltage to the third capacitor bank 1163 by connecting the node corresponding to the third capacitor bank 1163 to the node corresponding to the first power control circuit 1150, and supplying the fourth reference voltage to the fourth capacitor bank 1164 by connecting the node corresponding to the fourth capacitor bank 1164 to the node corresponding to the third resistance divider 1143; 1243a,1243b. The switch 1170; 1271,1272,1273,1274 may be configured to, based on the first supply voltage being included in the fourth reference range, supply the first reference voltage to the first capacitor bank 1161 by connecting the node corresponding to the first capacitor bank 1161 to the node corresponding to the battery 189, supply the second reference voltage to the second capacitor bank 1162 by connecting the node corresponding to the second capacitor bank 1162 to the node corresponding to the first resistance divider 1141; 1241a,1241b, supply the first supply voltage to the third capacitor bank 1163 by connecting the node corresponding to the third capacitor bank 1163 to the node corresponding to the second resistance divider 1142; 1242a, 1242b, and supply the first supply voltage to the fourth capacitor bank 1164 by connecting the node corresponding to the fourth capacitor bank 1164 to the node corresponding to the first power control circuit 1150.

According to an embodiment, the first resistance divider 1141; 1241a, 1241b may include a first resistor 1241a and a second resistor 1241b. The second capacitor bank 1162 may be connectable in parallel to the second resistor 1241b based on an operation of the switch 1170; 1271,1272,1273,1274.

According to an embodiment, the switch 1170; 1271,1272,1273,1274 may include a first switch 1271, a second switch 1272, a third switch 1273, and a fourth switch 1274. The first switch 1271 may be configured to selectively connect the node corresponding to the first capacitor bank 1161 to the node corresponding to the battery 189. The first switch 1271 may be configured to selectively connect the node corresponding to the second capacitor bank 1162 to the node corresponding to the first resistance divider 1141; 1241a, 1241b. The second switch 1272 may be configured to selectively connect the node corresponding to the third capacitor bank 1163 to the node corresponding to the second resistance divider 1142; 1242a,1242b. The second switch 1272 may be configured to selectively connect the node corresponding to the fourth capacitor bank 1164 to the node corresponding to the third resistance divider 1143; 1243a,1243b. The third switch 1273 may be configured to selectively connect the node corresponding to the first capacitor bank 1161 to the fourth switch 1274. The third switch 1273 may be configured to selectively connect the node corresponding to the second capacitor bank 1162 to the fourth switch 1274. The third switch 1273 may be configured to selectively connect the node corresponding to the third capacitor bank 1163 to the fourth switch 1274. The third switch 1273 may be configured to selectively connect the node corresponding to the fourth capacitor bank 1164 to the fourth switch 1274. The fourth switch 1274 may be configured to selectively connect the node corresponding to the first power control circuit 1150 to a first node or a second node of the third switch 1273.

According to an embodiment, the electronic device 101 may comprise a second power control circuit 1352 configured to supply a second supply voltage which is based on the transmission power and a second power amplifier 1382 configured to amplify a second RF signal, based on the second supply voltage. The second power control circuit 1352 may be configured to supply a second supply voltage adjusted based on the output power. The second power amplifier 1382 may be configured to amplify a second RF signal based on the second supply voltage. The switch 1370 may be configured to selectively connect the node corresponding to one of the plurality of capacitor banks 761; 762; 1161; 1162; 1163; 1164; 1361; 1362 to a node corresponding to the second power control circuit 1352, among the plurality of nodes, based on the second supply voltage.

According to an embodiment, a method for operating an electronic device may comprise adjusting a first supply voltage supplied from a first power control circuit 750; 1150; 1351 to a first power amplifier 780; 1180; 1381 based on transmission power (e.g., output power). The method may comprise amplifying a first RF signal based on the first supply voltage. The method may comprise, based on the first supply voltage being included in a first reference range, supplying the first supply voltage to the first capacitor bank 761; 1161; 1361 by connecting a node corresponding to the first power control circuit 750; 1150; 1351 among a plurality of nodes of a switch 770; 1170; 1271,1272,1273,1274; 1370 to a node corresponding to the first capacitor bank 761; 1161; 1361, among the plurality of nodes. The method may comprise, based on the first supply voltage being included in a second reference range, supplying the first supply voltage to the second capacitor bank 762; 1162; 1362 by connecting the node corresponding to the first power control circuit 750; 1150; 1351 to a node corresponding to a second capacitor bank 762; 1162; 1362, among the plurality of nodes, and supplying a first reference voltage to the first capacitor bank 761; 1161; 1361 by connecting a node corresponding to a battery 189, among the plurality of nodes, to the node corresponding to the first capacitor bank 761; 1161; 1361.

According to an embodiment, in the method, the amplified first RF signal may be provided from the first power amplifier 780; 1180; 1381 to an antenna 242, 244, 246, 248 for communication between the electronic device 101 and an external device 102. The first supply voltage may be adjusted based on a level of the transmission power (e.g., output power) for the communication.

According to an embodiment, in the method, the first reference range may comprise voltages greater than or equal to the first reference voltage. The second reference range comprises voltages less than the first reference voltage.

According to an embodiment, in the method, a capacitance of the second capacitor bank 762 may be smaller than a capacitance of the first capacitor bank 761.

According to an embodiment, the method may comprise selectively connecting the node corresponding to the second capacitor bank 1162 to a node corresponding to a first resistance divider 1141; 1241a,1241b of the electronic device 101, among the plurality of nodes. The method may comprise selectively connecting a node corresponding to a third capacitor bank 1163 of the electronic device 101, among the plurality of nodes, to a node corresponding to a second resistance divider 1142; 1242a, 1242b of the electronic device 101, among the plurality of nodes. The method may comprise selectively connecting a node corresponding to a fourth capacitor bank 1164 of the electronic device 101 to a node corresponding to a third resistance divider 1143; 1243a,1243b of the electronic device 101. The first resistance divider 1141; 1241a,1241b may be electrically connected to the battery 189. The second resistance divider 1142; 1242a,1242b may be electrically connected to the battery 189. The third resistance divider 1143; 1243a, 1243b may be electrically connected to the battery 189.

According to an embodiment, in the method, the first reference range may comprise voltages greater than or equal to the first reference voltage. The second reference range may comprise voltages less than the first reference voltage and greater than or equal to a second reference voltage. The third reference range may comprise voltages less than the second reference voltage and greater than or equal to a third reference voltage. The fourth reference range may comprise voltages less than the third reference voltage. The method may comprise, based on the first supply voltage being included in the first reference range, supplying the first supply voltage to the first capacitor bank 1161 by connecting the node corresponding to the first capacitor bank 1161 to the node corresponding to the first power control circuit 1150, supplying the second reference voltage to the second capacitor bank 1162 by connecting the node corresponding to the second capacitor bank 1162 to the node corresponding to the first resistance divider 1141; 1241a, 1241b, supplying the third reference voltage to the third capacitor bank 1163 by connecting the node corresponding to the third capacitor bank 1163 to the node corresponding to the second resistance divider 1142; 1242a, 1242b, and supplying a fourth reference voltage to the fourth capacitor bank 1164 by connecting the node corresponding to the fourth capacitor bank 1164 to the node corresponding to the third resistance divider 1143; 1243a,1243b. The method may comprise, based on the first supply voltage being included in the second reference range, supplying the first reference voltage to the first capacitor bank 761; 1161; 1361 by connecting the node corresponding to the first capacitor bank 1161 to the node corresponding to the battery 189, supplying the first supply voltage to the second capacitor bank 1162 by connecting the node corresponding to the second capacitor bank 1162 to the node corresponding to the first power control circuit 1150, supply the third reference voltage to the third capacitor bank 1163 by connecting the node corresponding to the third capacitor bank 1163 to the node corresponding to the second resistance divider 1142; 1242a,1242b, and supplying the fourth reference voltage to the fourth capacitor bank 1164 by connecting the node corresponding to the fourth capacitor bank 1164 to the node corresponding to the third resistance divider 1143; 1243a, 1243b. The method may comprise, based on the first supply voltage being included in the third reference range, supplying the first reference voltage to the first capacitor bank 1161 by connecting the node corresponding to the first capacitor bank 1161 to the node corresponding to the battery 189, supplying the second reference voltage to the second capacitor bank 1162 by connecting the node corresponding to the second capacitor bank 1162 to the node corresponding to the first resistance divider 1141; 1241a,1241b, supplying the first supply voltage to the third capacitor bank 1163 by connecting the node corresponding to the third capacitor bank 1163 to the node corresponding to the first power control circuit 1150, and supplying the fourth reference voltage to the fourth capacitor bank 1164 by connecting the node corresponding to the fourth capacitor bank 1164 to the node corresponding to the third resistance divider 1143; 1243a,1243b. The method may comprise, based on the first supply voltage being included in the fourth reference range, supplying the first reference voltage to the first capacitor bank 1161 by connecting the node corresponding to the first capacitor bank 1161 to the node corresponding to the battery 189, supplying the second reference voltage to the second capacitor bank 1162 by connecting the node corresponding to the second capacitor bank 1162 to the node corresponding to the first resistance divider 1141; 1241a,1241b, supplying the first supply voltage to the third capacitor bank 1163 by connecting the node corresponding to the third capacitor bank 1163 to the node corresponding to the second resistance divider 1142; 1242a,1242b, and supplying the first supply voltage to the fourth capacitor bank 1164 by connecting the node corresponding to the fourth capacitor bank 1164 to the node corresponding to the first power control circuit 1150.

According to an embodiment, in the method, the first resistance divider 1141; 1241a, 1241b may include a first resistor 1241a and a second resistor 1241b. The second capacitor bank 1162 may be connectable in parallel to the second resistor 1241b based on an operation of the switch 1170; 1271,1272,1273,1274.

According to an embodiment, in the method, the switch 1170; 1271,1272,1273,1274 may include a first switch 1271, a second switch 1272, a third switch 1273, and a fourth switch 1274. The first switch 1271 may be configured to selectively connect the node corresponding to the first capacitor bank 1161 to the node corresponding to the battery 189. The first switch 1271 may be configured to selectively connect the node corresponding to the second capacitor bank 1162 to the node corresponding to the first resistance divider 1141; 1241a,1241b. The second switch 1272 may be configured to selectively connect the node corresponding to the third capacitor bank 1163 to the node corresponding to the second resistance divider 1142; 1242a,1242b. The second switch 1272 may be configured to selectively connect the node corresponding to the fourth capacitor bank 1164 to the node corresponding to the third resistance divider 1143; 1243a,1243b. The third switch 1273 may be configured to selectively connect the node corresponding to the first capacitor bank 1161 to the fourth switch 1274. The third switch 1273 may be configured to selectively connect the node corresponding to the second capacitor bank 1162 to the fourth switch 1274. The third switch 1273 may be configured to selectively connect the node corresponding to the third capacitor bank 1163 to the fourth switch 1274. The third switch 1273 may be configured to selectively connect the node corresponding to the fourth capacitor bank 1164 to the fourth switch 1274. The fourth switch 1274 may be configured to selectively connect the node corresponding to the first power control circuit 1150 to a first node or a second node of the third switch 1273.

According to an embodiment, the method may comprise adjusting a second supply voltage supplied from a second power control circuit 1352 to a second power amplifier 1382 based on transmission power (e.g., output power). The method may comprise amplifying a second RF signal based on the second supply voltage. The method may comprise selectively connecting the node corresponding to one of the plurality of capacitor banks 761; 762; 1161; 1162; 1163; 1164; 1361; 1362 to a node corresponding to the second power control circuit 1352, among the plurality of nodes, based on the second supply voltage.

According to an embodiment, there may be provided a computer-readable non-transitory storage medium storing instructions. The instructions may, when executed by at least one processor 120; 212,214; 260 of an electronic device 101, cause the electronic device 101 to perform at least one operation. The at least one operation may comprise adjusting a first supply voltage supplied from a first power control circuit 750; 1150; 1351 to a first power amplifier 780; 1180; 1381 based on transmission power (e.g., output power). The at least one operation may comprise amplifying a first RF signal based on the first supply voltage. The at least one operation may comprise, based on the first supply voltage being included in a first reference range, supplying the first supply voltage to a first capacitor bank 761; 1161; 1361 by connecting a node corresponding to the first power control circuit 750; 1150; 1351 among a plurality of nodes of a switch 770; 1170; 1271,1272,1273,1274; 1370 to a node corresponding to the first capacitor bank 761; 1161; 1361 among the plurality of nodes. The at least one operation may comprise, based on the first supply voltage being included in a second reference range, supplying the first supply voltage to a second capacitor bank 762; 1162; 1362 by connecting the node corresponding to the first power control circuit 750; 1150; 1351 to a node corresponding to the second capacitor bank 762; 1162; 1362, among the plurality of nodes, and supplying a first reference voltage to the first capacitor bank 761; 1161; 1361 by connecting a node corresponding to a battery 189, among the plurality of nodes, to the node corresponding to the first capacitor bank 761; 1161; 1361.

According to an embodiment, in the storage medium, the amplified first RF signal may be provided from the first power amplifier 780; 1180; 1381 to an antenna 242, 244, 246, 248 for communication between the electronic device 101 and an external device 102. The first supply voltage may be adjusted based on a level of the transmission power (e.g., output power) for the communication.

According to an embodiment, in the storage medium, the first reference range may comprise voltages greater than or equal to the first reference voltage. The second reference range may comprise voltages less than the first reference voltage.

According to an embodiment, in the storage medium, a capacitance of the second capacitor bank 762 may be smaller than a capacitance of the first capacitor bank 761.

According to an embodiment, in the storage medium, the at least one operation may comprise selectively connecting the node corresponding to the second capacitor bank 1162 to a node corresponding to a first resistance divider 1141; 1241a,1241b of the electronic device 101, among the plurality of nodes. The at least one operation may comprise selectively connecting a node corresponding to a third capacitor bank 1163 of the electronic device 101, among the plurality of nodes, to a node corresponding to a second resistance divider 1142; 1242a, 1242b of the electronic device 101, among the plurality of nodes. The at least one operation may comprise selectively connecting a node corresponding to a fourth capacitor bank 1164 of the electronic device 101 to a node corresponding to a third resistance divider 1143; 1243a,1243b of the electronic device 101. The first resistance divider 1141; 1241a, 1241b may be electrically connected to the battery 189. The second resistance divider 1142; 1242a,1242b may be electrically connected to the battery 189. The third resistance divider 1143; 1243a, 1243b may be electrically connected to the battery 189.

According to an embodiment, in the storage medium, the first reference range may comprise voltages greater than or equal to the first reference voltage. The second reference range may comprise voltages less than the first reference voltage and greater than or equal to a second reference voltage. The third reference range may comprise voltages less than the second reference voltage and greater than or equal to a third reference voltage. The fourth reference range may comprise voltages less than the third reference voltage. The at least one operation may comprise, based on the first supply voltage being included in the first reference range, supplying the first supply voltage to the first capacitor bank 1161 by connecting the node corresponding to the first capacitor bank 1161 to the node corresponding to the first power control circuit 1150, supplying the second reference voltage to the second capacitor bank 1162 by connecting the node corresponding to the second capacitor bank 1162 to the node corresponding to the first resistance divider 1141; 1241a,1241b, supplying the third reference voltage to the third capacitor bank 1163 by connecting the node corresponding to the third capacitor bank 1163 to the node corresponding to the second resistance divider 1142; 1242a,1242b, and supplying a fourth reference voltage to the fourth capacitor bank 1164 by connecting the node corresponding to the fourth capacitor bank 1164 to the node corresponding to the third resistance divider 1143; 1243a,1243b. The at least one operation may comprise, based on the first supply voltage being included in the second reference range, supplying the first reference voltage to the first capacitor bank 761; 1161; 1361 by connecting the node corresponding to the first capacitor bank 1161 to the node corresponding to the battery 189, supplying the first supply voltage to the second capacitor bank 1162 by connecting the node corresponding to the second capacitor bank 1162 to the node corresponding to the first power control circuit 1150, supply the third reference voltage to the third capacitor bank 1163 by connecting the node corresponding to the third capacitor bank 1163 to the node corresponding to the second resistance divider 1142; 1242a,1242b, and supplying the fourth reference voltage to the fourth capacitor bank 1164 by connecting the node corresponding to the fourth capacitor bank 1164 to the node corresponding to the third resistance divider 1143; 1243a,1243b. The at least one operation may comprise, based on the first supply voltage being included in the third reference range, supplying the first reference voltage to the first capacitor bank 1161 by connecting the node corresponding to the first capacitor bank 1161 to the node corresponding to the battery 189, supplying the second reference voltage to the second capacitor bank 1162 by connecting the node corresponding to the second capacitor bank 1162 to the node corresponding to the first resistance divider 1141; 1241a, 1241b, supplying the first supply voltage to the third capacitor bank 1163 by connecting the node corresponding to the third capacitor bank 1163 to the node corresponding to the first power control circuit 1150, and supplying the fourth reference voltage to the fourth capacitor bank 1164 by connecting the node corresponding to the fourth capacitor bank 1164 to the node corresponding to the third resistance divider 1143; 1243a, 1243b. The at least one operation may comprise, based on the first supply voltage being included in the fourth reference range, supplying the first reference voltage to the first capacitor bank 1161 by connecting the node corresponding to the first capacitor bank 1161 to the node corresponding to the battery 189, supplying the second reference voltage to the second capacitor bank 1162 by connecting the node corresponding to the second capacitor bank 1162 to the node corresponding to the first resistance divider 1141; 1241a, 1241b, supplying the first supply voltage to the third capacitor bank 1163 by connecting the node corresponding to the third capacitor bank 1163 to the node corresponding to the second resistance divider 1142; 1242a,1242b, and supplying the first supply voltage to the fourth capacitor bank 1164 by connecting the node corresponding to the fourth capacitor bank 1164 to the node corresponding to the first power control circuit 1150.

According to an embodiment, in the storage medium, the first resistance divider 1141; 1241a,1241b may include a first resistor 1241a and a second resistor 1241b. The second capacitor bank 1162 may be connectable in parallel to the second resistor 1241b based on an operation of the switch 1170; 1271,1272,1273,1274.

According to an embodiment, in the storage medium, the switch 1170; 1271,1272,1273,1274 may include a first switch 1271, a second switch 1272, a third switch 1273, and a fourth switch 1274. The first switch 1271 may be configured to selectively connect the node corresponding to the first capacitor bank 1161 to the node corresponding to the battery 189. The first switch 1271 may be configured to selectively connect the node corresponding to the second capacitor bank 1162 to the node corresponding to the first resistance divider 1141; 1241a,1241b. The second switch 1272 may be configured to selectively connect the node corresponding to the third capacitor bank 1163 to the node corresponding to the second resistance divider 1142; 1242a,1242b. The second switch 1272 may be configured to selectively connect the node corresponding to the fourth capacitor bank 1164 to the node corresponding to the third resistance divider 1143; 1243a,1243b. The third switch 1273 may be configured to selectively connect the node corresponding to the first capacitor bank 1161 to the fourth switch 1274. The third switch 1273 may be configured to selectively connect the node corresponding to the second capacitor bank 1162 to the fourth switch 1274. The third switch 1273 may be configured to selectively connect the node corresponding to the third capacitor bank 1163 to the fourth switch 1274. The third switch 1273 may be configured to selectively connect the node corresponding to the fourth capacitor bank 1164 to the fourth switch 1274. The fourth switch 1274 may be configured to selectively connect the node corresponding to the first power control circuit 1150 to a first node or a second node of the third switch 1273.

According to an embodiment, in the storage medium, the at least one operation may comprise adjusting a second supply voltage supplied from a second power control circuit 1352 to a second power amplifier 1382 based on transmission power (e.g., output power). The at least one operation may comprise amplifying a second RF signal based on the second supply voltage. The at least one operation may comprise selectively connecting the node corresponding to one of the plurality of capacitor banks 761; 762; 1161; 1162; 1163; 1164; 1361; 1362 to a node corresponding to the second power control circuit 1352, among the plurality of nodes, based on the second supply voltage.

The device according to various embodiments of the disclosure may be one of various types of electronic devices. The device may include, for example, a portable communication device (e.g., a smartphone), a computer device, a portable multimedia device, a portable medical device, a camera, a wearable device, or a home appliance. The devices according to an embodiment of the disclosure are not limited to the above-described devices.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (A SIC).

Various embodiments as set forth herein may be implemented as software (e.g., the program) including one or more instructions that are stored in a storage medium that is readable by a machine (e.g., an electronic device). For example, a processor (e.g., a controller) of the machine may invoke at least one of the one or more instructions stored in the storage medium, and execute it. This allows the machine to be operated to perform at least one function according to the at least one instruction invoked. The one or more instructions may include a code generated by a complier or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a first power control circuit configured to supply a first supply voltage which is based on transmission power;
a first power amplifier configured to amplify a first radio frequency (RF) signal, based on the first supply voltage;
a battery configured to provide at least one reference voltage;
a plurality of capacitor banks comprising a first capacitor bank and a second capacitor bank; and
a switch comprising a plurality of nodes and configured to selectively connect a node corresponding to one of the plurality of capacitor banks, among the plurality of nodes, to a node corresponding to the first power control circuit, among the plurality of nodes, based on the first supply voltage, wherein the switch is further configured to:
based on the first supply voltage being in a first reference range, supply the first supply voltage to the first capacitor bank by connecting the node corresponding to the first power control circuit to a node corresponding to the first capacitor bank among the plurality of nodes; and
based on the first supply voltage being in a second reference range, supply the first supply voltage to the second capacitor bank by connecting the node corresponding to the first power control circuit to a node corresponding to the second capacitor bank among the plurality of nodes, and supply a first reference voltage to the first capacitor bank by connecting a node corresponding to the battery, among the plurality of nodes, to the node corresponding to the first capacitor bank.

2. The electronic device of claim 1, further comprising:
an antenna,
wherein the first power amplifier is further configured to provide the amplified first RF signal to the antenna for communication between the electronic device and an external device, and
wherein the first power control circuit is further configured to supply the first supply voltage which is based on a level of the transmission power for the communication.

3. The electronic device of claim 1, wherein the first reference range comprises voltages greater than or equal to the first reference voltage, and
wherein the second reference range comprises voltages less than the first reference voltage.

4. The electronic device of claim 3, wherein a capacitance of the second capacitor bank is smaller than a capacitance of the first capacitor bank.

5. The electronic device of claim 1, further comprising:
a first resistance divider electrically connected to the battery;
a second resistance divider electrically connected to the battery; and
a third resistance divider electrically connected to the battery,
wherein the plurality of capacitor banks further comprises a third capacitor bank and a fourth capacitor bank, and
wherein the switch is further configured to:
selectively connect the node corresponding to the second capacitor bank to a node corresponding to the first resistance divider, among the plurality of nodes;
selectively connect a node corresponding to the third capacitor bank, among the plurality of nodes, to a node corresponding to the second resistance divider, among the plurality of nodes; and
selectively connect a node corresponding to the fourth capacitor bank, among the plurality of nodes, to a node corresponding to the third resistance divider, among the plurality of nodes.

6. The electronic device of claim 5, wherein the first reference range comprises voltages greater than or equal to the first reference voltage,
wherein the second reference range comprises voltages less than the first reference voltage and greater than or equal to a second reference voltage,
wherein a third reference range comprises voltages less than the second reference voltage and greater than or equal to a third reference voltage, and
wherein a fourth reference range comprises voltages less than the third reference voltage, and
wherein the switch is further configured to:
based on the first supply voltage being in the first reference range, supply the first supply voltage to the first capacitor bank by connecting the node corresponding to the first capacitor bank to the node corresponding to the first power control circuit, supply the second reference voltage to the second capacitor bank by connecting the node corresponding to the second capacitor bank to the node corresponding to the first resistance divider, supply the third reference voltage to the third capacitor bank by connecting the node corresponding to the third capacitor bank to the node corresponding to the second resistance divider, and supply a fourth reference voltage to the fourth capacitor bank by connecting the node corresponding to the fourth capacitor bank to the node corresponding to the third resistance divider;
based on the first supply voltage being in the second reference range, supply the first reference voltage to the first capacitor bank by connecting the node corresponding to the first capacitor bank to the node corresponding to the battery, supply the first supply voltage to the second capacitor bank by connecting the node corresponding to the second capacitor bank to the node corresponding to the first power control circuit, supply the third reference voltage to the third capacitor bank by connecting the node corresponding to the third capacitor bank to the node corresponding to the second resistance divider, and supply the fourth reference voltage to the fourth capacitor bank by connecting the node corresponding to the fourth capacitor bank to the node corresponding to the third resistance divider;
based on the first supply voltage being in the third reference range, supply the first reference voltage to the first capacitor bank by connecting the node corresponding to the first capacitor bank to the node corresponding to the battery, supply the second reference voltage to the second capacitor bank by connecting the node corresponding to the second capacitor bank to the node corresponding to the first resistance divider, supply the first supply voltage to the third capacitor bank by connecting the node corresponding to the third capacitor bank to the node corresponding to the first power control circuit, and supply the fourth reference voltage to the fourth capacitor bank by connecting the node corresponding to the fourth capacitor bank to the node corresponding to the third resistance divider; and
based on the first supply voltage being in the fourth reference range, supply the first reference voltage to the first capacitor bank by connecting the node corresponding to the first capacitor bank to the node corresponding to the battery, supply the second reference voltage to the second capacitor bank by connecting the node corresponding to the second capacitor bank to the node corresponding to the first resistance divider, supply the first supply voltage to the third capacitor bank by connecting the node corresponding to the third capacitor bank to the node corresponding to the second resistance divider, and supply the first supply voltage to the fourth capacitor bank by connecting the node corresponding to the fourth capacitor bank to the node corresponding to the first power control circuit.

7. The electronic device of claim 5, wherein the first resistance divider comprises a first resistor and a second resistor, and
wherein the second capacitor bank is connectable in parallel to the second resistor based on an operation of the switch.

8. The electronic device of claim 5, wherein the switch comprises a first switch, a second switch, a third switch, and a fourth switch,
wherein the first switch is further configured to:
selectively connect the node corresponding to the first capacitor bank to the node corresponding to the battery; and
selectively connect the node corresponding to the second capacitor bank to the node corresponding to the first resistance divider,
wherein the second switch is configured to:
selectively connect the node corresponding to the third capacitor bank to the node corresponding to the second resistance divider; and
selectively connect the node corresponding to the fourth capacitor bank to the node corresponding to the third resistance divider,
wherein the third switch is configured to:
selectively connect the node corresponding to the first capacitor bank to the fourth switch;
selectively connect the node corresponding to the second capacitor bank to the fourth switch;
selectively connect the node corresponding to the third capacitor bank to the fourth switch; and
selectively connect the node corresponding to the fourth capacitor bank to the fourth switch, and
wherein the fourth switch is configured to:
selectively connect the node corresponding to the first power control circuit to a first node or a second node of the third switch.

9. The electronic device of claim 3, further comprising:
a second power control circuit configured to supply a second supply voltage which is based on the transmission power; and
a second power amplifier configured to amplify a second RF signal, based on the second supply voltage,
wherein the switch is further configured to selectively connect the node corresponding to one of the plurality of capacitor banks to a node corresponding to the second power control circuit, among the plurality of nodes, based on the second supply voltage.

10. A method for operating an electronic device, the method comprising:
adjusting a first supply voltage supplied from a first power control circuit to a first power amplifier based on transmission power;
amplifying a first radio frequency (RF) signal based on the first supply voltage;
based on the first supply voltage being in a first reference range, supplying the first supply voltage to a first capacitor bank by connecting a node corresponding to the first power control circuit, among a plurality of nodes of a switch, to a node corresponding to the first capacitor bank, among the plurality of nodes; and
based on the first supply voltage being in a second reference range, supplying the first supply voltage to a second capacitor bank by connecting the node corresponding to the first power control circuit to a node corresponding to the second capacitor bank, among the plurality of nodes, and supplying a first reference voltage to the first capacitor bank by connecting a node corresponding to a battery, among the plurality of nodes, to the node corresponding to the first capacitor bank.

11. The method of claim 10, wherein the amplified first RF signal is provided from the first power amplifier to an antenna for communication between the electronic device and an external device, and
wherein the first supply voltage is adjusted based on a level of the transmission power for the communication.

12. The method of claim 10, wherein the first reference range comprises voltages greater than or equal to the first reference voltage, and
wherein the second reference range comprises voltages less than the first reference voltage.

13. The method of claim 12, wherein a capacitance of the second capacitor bank is smaller than a capacitance of the first capacitor bank.

14. The method of claim 11, further comprising:
selectively connecting the node corresponding to the second capacitor bank to a node corresponding to a first resistance divider of the electronic device, among the plurality of nodes;
selectively connecting a node corresponding to a third capacitor bank of the electronic device, among the plurality of nodes, to a node corresponding to a second resistance divider of the electronic device, among the plurality of nodes; and
selectively connecting a node corresponding to a fourth capacitor bank of the electronic device to a node corresponding to a third resistance divider of the electronic device,
wherein the first resistance divider is electrically connected to the battery,
wherein the second resistance divider is electrically connected to the battery, and
wherein the third resistance divider is electrically connected to the battery.

15. A computer-readable non-transitory storage medium storing instructions that, when executed by at least one processor of an electronic device, cause the electronic device to perform at least one operation comprising:
adjusting a first supply voltage supplied from a first power control circuit to a first power amplifier based on transmission power;
amplifying a first radio frequency (RF) signal based on the first supply voltage;
based on the first supply voltage being in a first reference range, supplying the first supply voltage to a first capacitor bank by connecting a node corresponding to the first power control circuit, among a plurality of nodes of a switch, to a node corresponding to the first capacitor bank, among the plurality of nodes; and
based on the first supply voltage being in a second reference range, supplying the first supply voltage to a second capacitor bank by connecting the node corresponding to the first power control circuit to a node corresponding to the second capacitor bank, among the plurality of nodes, and supplying a first reference voltage to the first capacitor bank by connecting a node corresponding to a battery, among the plurality of nodes, to the node corresponding to the first capacitor bank.

16. The computer-readable non-transitory storage medium of claim 15, wherein the amplified first RF signal is provided from the first power amplifier to an antenna for communication between the electronic device and an external device, and
wherein the first supply voltage is adjusted based on a level of the transmission power for the communication.

17. The computer-readable non-transitory storage medium of claim 15, wherein the first reference range comprises voltages greater than or equal to the first reference voltage,
wherein the second reference range comprises voltages less than the first reference voltage.

18. The computer-readable non-transitory storage medium of claim 15, wherein a capacitance of the second capacitor bank is smaller than a capacitance of the first capacitor bank.

19. The computer-readable non-transitory storage medium of claim 15, wherein the at least one operation further comprise:
selectively connecting the node corresponding to the second capacitor bank to a node corresponding to a first resistance divider of the electronic device, among the plurality of nodes;
selectively connecting a node corresponding to a third capacitor bank of the electronic device, among the plurality of nodes, to a node corresponding to a second resistance divider of the electronic device, among the plurality of nodes; and
selectively connecting a node corresponding to a fourth capacitor bank of the electronic device, among the plurality of nodes, to a node corresponding to a third resistance divider of the electronic device, among the plurality of nodes,
wherein the first resistance divider is electrically connected to the battery,
wherein the second resistance divider is electrically connected to the battery, and
wherein the third resistance divider is electrically connected to the battery.

20. The computer-readable non-transitory storage medium of claim 19, wherein the first reference range comprises voltages greater than or equal to the first reference voltage,
wherein the second reference range comprises voltages less than the first reference voltage and greater than or equal to a second reference voltage,
wherein a third reference range comprises voltages less than the second reference voltage and greater than or equal to a third reference voltage, and
wherein a fourth reference range comprises voltages less than the third reference voltage, and
wherein the at least one operation further comprise:
based on the first supply voltage being in the first reference range, supplying the first supply voltage to the first capacitor bank by connecting the node corresponding to the first capacitor bank to the node corresponding to the first power control circuit, supplying the second reference voltage to the second capacitor bank by connecting the node corresponding to the second capacitor bank to the node corresponding to the first resistance divider, supplying the third reference voltage to the third capacitor bank by connecting the node corresponding to the third capacitor bank to the node corresponding to the second resistance divider, and supplying a fourth reference voltage to the fourth capacitor bank by connecting the node corresponding to the fourth capacitor bank to the node corresponding to the third resistance divider,
based on the first supply voltage being in the second reference range, supplying the first reference voltage to the first capacitor bank by connecting the node corresponding to the first capacitor bank to the node corresponding to the battery, supplying the first supply voltage to the second capacitor bank by connecting the node corresponding to the second capacitor bank to the node corresponding to the first power control circuit, supplying the third reference voltage to the third capacitor bank by connecting the node corresponding to the third capacitor bank to the node corresponding to the second resistance divider, and supplying the fourth reference voltage to the fourth capacitor bank by connecting the node corresponding to the fourth capacitor bank to the node corresponding to the third resistance divider,
based on the first supply voltage being in the third reference range, supplying the first reference voltage to the first capacitor bank by connecting the node corresponding to the first capacitor bank to the node corresponding to the battery, supplying the second reference voltage to the second capacitor bank by connecting the node corresponding to the second capacitor bank to the node corresponding to the first resistance divider, supplying the first supply voltage to the third capacitor bank by connecting the node corresponding to the third capacitor bank to the node corresponding to the first power control circuit, and supplying the fourth reference voltage to the fourth capacitor bank by connecting the node corresponding to the fourth capacitor bank to the node corresponding to the third resistance divider, and
based on the first supply voltage being in the fourth reference range, supplying the first reference voltage to the first capacitor bank by connecting the node corresponding to the first capacitor bank to the node corresponding to the battery, supplying the second reference voltage to the second capacitor bank by connecting the node corresponding to the second capacitor bank to the node corresponding to the first resistance divider, supplying the first supply voltage to the third capacitor bank by connecting the node corresponding to the third capacitor bank to the node corresponding to the second resistance divider, and supplying the first supply voltage to the fourth capacitor bank by connecting the node corresponding to the fourth capacitor bank to the node corresponding to the first power control circuit.
